(19) United States
(12) Patent Application Publication
(10) Pub. No.: US 2018/0321563 A1
(43) Pub. Date: Nov. 8, 2018

(54) DISPLAY DEVICE

(71) Applicant: Japan Display Inc., Minato-ku (JP)

(72) Inventors: Hidetatsu NAKAMURA, Tokyo (JP); Gen Koide, Tokyo (JP)

(73) Assignee: Japan Display Inc., Minato-ku (JP)

(21) Appl. No.: 15/952,304

(22) Filed: Apr. 13, 2018

(30) Foreign Application Priority Data
May 2, 2017 (JP) 2017-091825

(51) Int. Cl. G02F 1/1362; H01L 27/12; G02F 1/1339; G02F 1/1333; G02F 1/1343; G02F 1/1335; G02F 1/1368; G02F 1/1345

(52) U.S. Cl. CPC G02F 1/136286; G02F 1/1337; G02F 1/1339; G02F 1/133345; G02F 1/136227; G02F 1/13439; G02F 1/13394; G02F 1/133514; G02F 1/1368; G02F 1/13458; G02F 1/133305; G02F 2001/13685; G02F 1/13452; G02F 2203/01; G02F 1/13338; G02F 2203/02; G02F 2203/09; G02F 1/134309; G02F 2201/124; H01L 27/124

(57) ABSTRACT

According to one embodiment, a display device includes a first basement, a second basement having a first hole, a first conducive layer located between the first and the second basements, a sealant located between the first conductive layer and the second basement and having a second hole which is continuous with the first hole, an organic insulating layer located between the first conductive layer and the sealant and having a third hole which is continuous with the second hole, a second conductive layer located on a surface of the second basement, and a connecting material electrically connecting the first conductive layer and the second conductive layer via the first hole to third hole.

### CROSS-REFERENCE TO RELATED APPLICATIONS

This application is based upon and claims the benefit of priority from Japanese Patent Application No. 2017-091825, filed May 2, 2017, the entire contents of which are incorporated herein by reference.

### FIELD

Embodiments described herein relate generally to a display device.

### BACKGROUND

Recently, various techniques for narrowing the frames of display devices have been considered. An example of the techniques which have been disclosed is that a wiring portion which has an in-hole connection portion in a hole through the inner surface and outer surface of a first resin substrate and a wiring portion which is provided on the inner surface of a second resin substrate are electrically connected to each other by an intersubstrate connection portion.

### BRIEF DESCRIPTION OF THE DRAWINGS

FIG. 1 is a plan view schematically showing a display device according to the present embodiment.

FIG. 2 is a diagram showing the equivalent circuit of the display device shown in FIG. 1.

FIG. 3 is a sectional view schematically showing a display area of the display device shown in FIG. 1.

FIG. 4 is a sectional view showing the connection relationship between a switching element and a pixel electrode.

FIG. 5 is a plan view schematically showing a sensor mounted on the display device shown in FIG. 1.

FIG. 6 is an enlarged view of a detection electrode of the display device shown in FIG. 1.

FIG. 7 is an enlarged plan view of a pad shown in FIG. 1.

FIG. 8 is a sectional view schematically showing a non-display area of the display device shown in FIG. 1.

FIG. 9 is a sectional view showing the first modification of the display device of the present embodiment.

FIG. 10 is a sectional view showing the second modification of the display device of the present embodiment.

FIG. 11 is a sectional view showing the third modification of the display device of the present embodiment.

FIG. 12 is a sectional view showing the fourth modification of the display device of the present embodiment.

FIG. 13 is a sectional view showing the fifth modification of the display device of the present embodiment.

FIG. 14 is a sectional view showing the sixth modification of the display device of the present embodiment.

FIG. 15 is a plan view showing the positional relationship of a groove 12c shown in FIG. 14 to a pad P1 and a transparent conductive layer TC1.

FIG. 16 is a sectional view showing the seventh modification of the display device of the present embodiment.

FIG. 17 is a sectional view showing the eight modification of the display device of the present embodiment.

FIG. 18 is a plan view showing the positional relationship of a groove 13b shown in FIG. 17 to transparent conductive layers TC1 and TC2.

FIG. 19 is a sectional view showing the ninth modification of the display device of the present embodiment.

FIG. 20 is a plan view showing the positional relationship of a groove 12d shown in FIG. 19 to the pad P1, the transparent conductive layer TC1 and the transparent conductive layer TC2.

FIG. 21 is a sectional view showing the tenth modification of the display device of the present embodiment.

FIG. 22 is a sectional view showing the eleventh modification of the display device of the present embodiment.

FIG. 23 is a sectional view showing the twelfth modification of the display device of the present embodiment.

FIG. 24 is a plan view showing the thirteenth modification of the display device of the present embodiment.

FIG. 25 is a plan view showing the fourteenth modification of the display device of the present embodiment.

FIG. 26 is a sectional view taken along line C-D of FIG. 25.

FIG. 27 is a plan view showing the fifteenth modification of the display device of the present embodiment.

FIG. 28 is a sectional view taken along line E-F of FIG. 27.

### DETAILED DESCRIPTION

In general, according to one embodiment, a display device includes a first basement, a second basement which is opposed to the first basement and has a first hole, a first conducive layer which is located between the first basement and the second basement and is opposed to the first hole, a sealant which is located between the first conductive layer and the second basement and has a second hole which is continuous with the first hole, an organic insulating layer which is located between the first conductive layer and the sealant and has a third hole which is continuous with the second hole, a second conductive layer which is located on a surface of the second basement opposite to a surface of the second basement which is opposed to the first basement, and a connecting material which electrically connects the first conductive layer and the second conductive layer via the first hole to third hole.

According to another embodiment, a display device comprising a first basement, a second basement which is opposed to the first basement and has a first hole, a first conductive layer which is located between the first basement and the second basement and is opposed to the first hole, a sealant which is located between the first conductive layer and the second basement and has a second hole which is continuous with the first hole, a second conductive layer which is located on a surface of the second basement opposite to a surface of the second basement which is opposed to the first basement, and a connecting material which electrically connects the first conductive layer and the second conductive layer via the first hole and the second hole, wherein the first conductive layer is a transparent conductive layer.

Embodiments will be described hereinafter with reference to the accompanying drawings. Incidentally, the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the structural elements having functions, which are identical or similar to the functions of the structural elements described in connection with preceding drawings, are denoted by like reference numerals, and an overlapping detailed description is omitted unless otherwise necessary.

A display device of the present embodiment can be used in various devices such as smartphones, tablet computers, mobile phones, notebook computers and game consoles, for example. The main structure disclosed in the present embodiment is applicable to liquid crystal displays, self-luminance display devices such as organic electroluminescent display devices, electronic paper-type display devices having electrophoretic elements, display devices adopting micro-electromechanical systems (MEMS), display devices adopting electrochromism, etc.

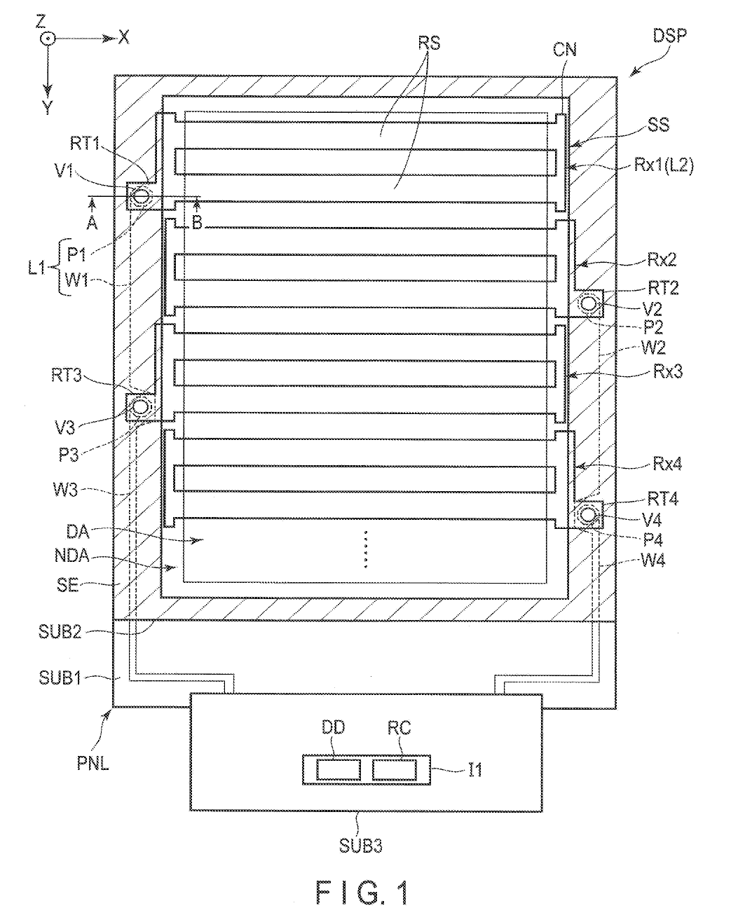

FIG. 1 is a plan view showing an example of the structure of a display device DSP of the present embodiment. Here, a liquid crystal display device equipped with a sensor SS will be described as an example of the display device DSP.

A first direction X, a second direction Y and a third direction Z shown in the drawing perpendicularly intersect each other, but the first direction X and the second direction Y may intersect each other at an angle other than an angle of 90 degrees. The first direction X and the second direction Y correspond to directions parallel to the surfaces of substrates which constitute the display device DSP, and for example, the first direction X is parallel to the short sides of the display device DSP and the second direction Y is parallel to the long sides of the display device DSP. The third direction Z corresponds to the thickness direction of the display device DSP.

In the following description, the third direction Z is referred to as an upper side (or simply above), and the direction opposite to the third direction Z is referred to as a lower side (or simply below). Such expressions as “a second member above a first member” and “a second member below a first member” mean that the second member may be in contact with the first member or may be away from the first member. In the latter case, a third member may be interposed between the first member and the second member. Further, a view of an X-Y plane defined by the first direction X and the second direction Y in the direction opposite to the third direction Z is referred to as a plan view. A view of a cross-section of the display device DSP in an X-Z plane defined by the first direction X and the third direction Z or a Y-Z plane defined by the second direction Y and the third direction Z is referred to as a sectional view.

FIG. 1 is a plan view showing part of the display device DSP in the X-Y plane defined by the first direction X and the second direction Y. The display device DSP includes a display panel PNL, an IC chip I1, a wiring substrate SUB3, etc.

The display panel PNL is a liquid crystal display panel and includes a first substrate SUB1, a second substrate SUB2, a sealant SE and a display function layer (liquid crystal layer LC which will be described later). The first substrate SUB1 and the second substrate SUB2 are opposed to each other in the third direction Z. In the example illustrated, the second substrate SUB2 is provided above the first substrate SUB1. The sealant SE is provided at a position shaded with rising diagonal lines in FIG. 1 and attaches the first substrate SUB1 and the second substrate SUB2 to each other. The display function layer is held between the first substrate SUB1 and the second substrate SUB2.

The display panel PNL has a display area DA and a non-display area (peripheral area) NDA. The display area DA is an area for displaying an image, and is surrounded by the sealant SE and is located on the inner side from the sealant SE. The non-display area NDA is located outside the display area DA and surrounds the display area DA. The sealant SE is located in the non-display area NDA.

The wiring substrate SUB3 is mounted on the first substrate SUB1. This wiring substrate SUB3 is a flexible substrate, for example. As the flexible substrate applicable to the present embodiment, at least part of the flexible substrate includes a flexible portion formed of a bendable material. For example, the wiring substrate SUB3 of the present embodiment may be a flexible substrate which is entirely formed as a flexible portion or may be a rigid-flexible substrate which includes a rigid portion formed of a rigid material such as glass epoxy and a flexible portion formed of a bendable material such as polyimide.

The IC chip I1 is mounted on the wiring substrate SUB3. The IC chip I1 is not limited to the example illustrated and may be mounted on the first substrate SUB1 which extends outward beyond the second substrate SUB2 or may be mounted on an external circuit board which is connected to the wiring substrate SUB3. The IC chip I1 includes a built-in display driver DD which outputs a signal necessary for image display, for example. The display driver DD here includes at least some of a signal line driver SD, a scanning line driver GD and a common electrode driver CD which will be described later. Further, in the example illustrated, the IC chip I1 includes a built-in detection circuit RC which functions as a touch panel controller. The detection circuit RC may be incorporated in an IC chip other than the IC chip I1 instead.

The display panel PNL may be a transmissive display panel which has a transmissive display function of displaying an image by selectively transmitting light from below the first substrate SUB1 (the side opposite to the display surface side), a reflective display panel which has a reflective display function of displaying an image by selectively transmitting light from above the second substrate SUB2 (the display surface side) or a transreflective display panel which has the transmissive display function and the reflective display function.

The sensor SS mounted on the display device DSP performs sensing to detect contact or approach of an object to the display device DSP. The sensor SS includes a plurality of detection electrodes Rx (Rx1, Rx2 . . . ). The detection electrodes Rx are provided on the second substrate SUB2. The detection electrodes Rx extend in the first direction X and are arranged at intervals in the second direction Y. FIG. 1 shows detection electrodes Rx1 to Rx4 as the detection electrodes Rx, but an example of the structure of the detection electrode Rx1 will be described below.

That is, the detection electrode Rx1 includes a detector RS, a terminal RT1 and a connector CN.

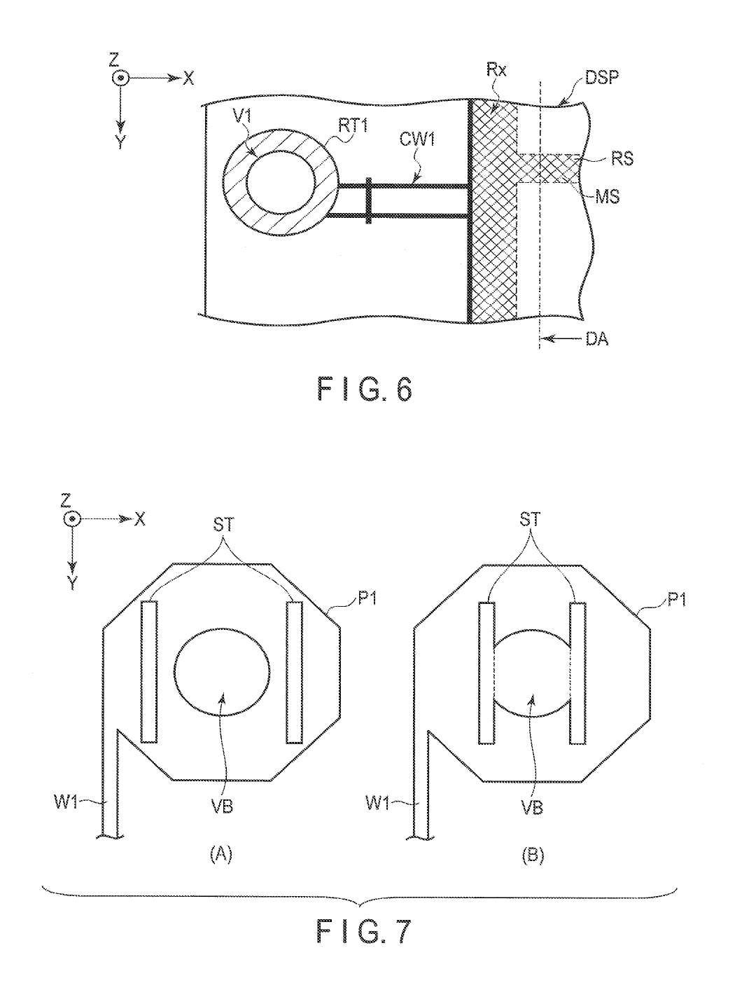

The detector RS is located in the display area DA and extends in the first direction X. In the detection electrode Rx1, the detector RS is mainly used for sensing. In the example illustrated, the detector RS is formed into a strip, and more specifically, the detector RS is formed of an aggregate of fine metal lines as will be described later with reference to FIG. 6. Further, one detection electrode Rx1 includes two detectors RS but may include three or more detectors RS or may include one detector RS.

The terminal RT1 is located on one end side of the non-display area NDA in the first direction X, that is, the terminal RT1 is located in an area of the non-display area NDA which extends in the second direction Y and is continuous with the detector RS. Part of the terminal RT1 overlaps the sealant SE.

The connector CN is located on the other end side of the non-display area NDA in the first direction X, that is, the connector CN is located in an area of the non-display area NDA which extends in the second direction Y on the side opposite to the terminal RT1. The connector CN connects the detectors RS to each other. In FIG. 1, one end side corresponds to the left side from the display area DA, and the other end side corresponds to the right side from the display area DA.

Meanwhile, the first substrate SUB1 includes a pad P1 and a wiring line W1. The pad P1 and the wiring line W1 are located on one end side of the non-display area NDA and overlap the sealant SE in a plan view. The pad P1 is formed at a position which overlaps the terminal RT1 in a plan view. The wiring line W1 is connected to the pad P1, extends in the second direction Y, and is electrically connected to the detection circuit RC of the IC chip I1 via the wiring substrate SUB3.

The display panel PNL has a contact hole V1 which electrically connects the pad P1 and the detection electrode Rx in the non-display area NDA. In the present embodiment, the pad P1 corresponds to a first conductive layer L1, and the detection electrode Rx corresponds to a second conductive layer L2.

The contact hole V1 is formed at a position at which the terminal RT1 and the pad P1 are opposed to each other. Further, the contact hole V1 penetrates the second substrate SUB2, which includes the terminal RT1, and the sealant SE, and the contact hole V1 may also penetrate the pad P1 in some cases. The contact hole V1 has a circular shape in a plan view in the example illustrated, but the contact hole V1 does not necessarily have the illustrated shape and may have another shape such as an elliptical shape.

A connecting material which electrically connects the terminal RT1 (that is, the second conductive layer L2) and the pad P1 (that is, the first conductive layer L1) is provided in the contact hole V1. Accordingly, the detection electrode Rx1 which is provided on the second substrate SUB2 is electrically connected to the detection circuit RC via the wiring substrate SUB3 which is connected to the first substrate SUB1. The detection circuit RC reads a sensor signal output from the detection electrode Rx, and detects the presence or absence of contact or approach of an object, the position coordinates of an object, etc.

In the example illustrated, terminals RT1, RT3 . . . of odd-numbered detection electrodes Rx1, Rx3 . . . , pads P1, P3 . . . , wiring lines W1, W3 . . . , and contact holes V1, V3 . . . are located on one end side of the non-display area NDA. Further, terminals RT2, RT4 . . . of even-numbered detection electrodes Rx2, Rx4 . . . , pads P2, P4 . . . , wiring lines W2, W4 . . . , and contact holes V2, V4 . . . are located on the other end side of the non-display area NDA. According to this layout, the width of one end side of the non-display area NDA and the width of the other end side of the non-display area NDA become uniform, and this is favorable for narrowing the frame.

As illustrated in the drawing, when the pad P3 is closer to the wiring substrate SUB3 than the pad P1, the wiring line W1 is arranged on the inner side from the pad P3 (that is, the side closer to the display area DA) in such a manner as to avoid the pad P3 and is then arranged along the wiring line W3 on the inner side from the wiring line W3 between the pad P3 and the wiring substrate SUB3. Similarly, the wiring line W2 is arranged on the inner side from the pad P4 in such a manner as to avoid the pad P4 and is then arranged along the wiring line W4 on the inner side from the wiring line W4 between the pad P4 and the wiring substrate SUB3.

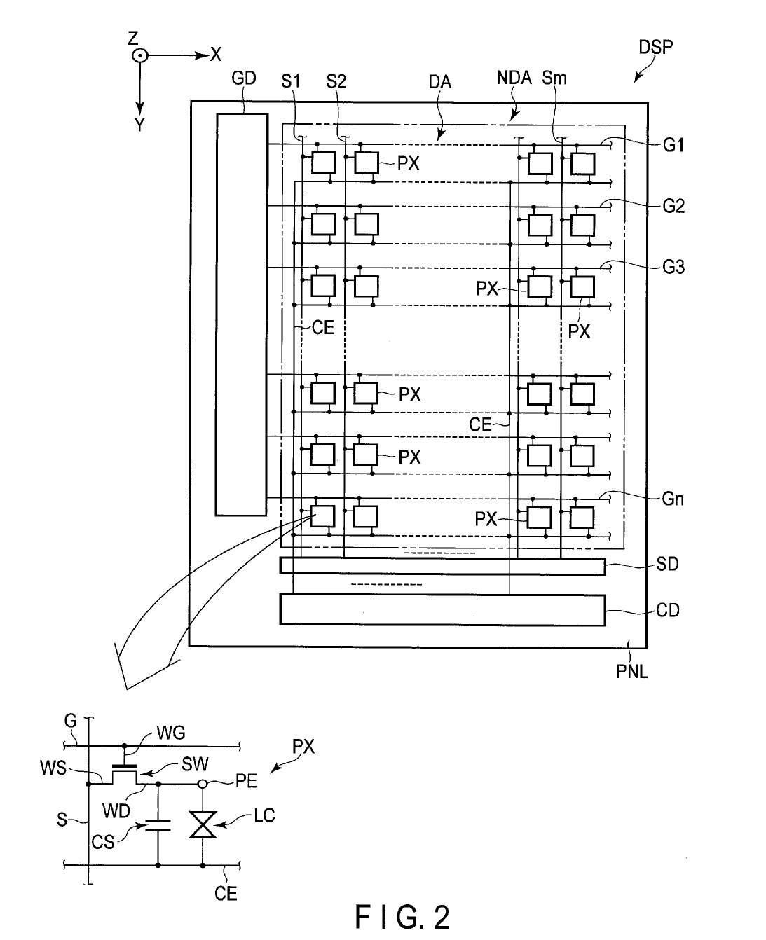

FIG. 2 shows the basic structure and equivalent circuit of the display panel PNL shown in FIG. 1.

The display panel PNL includes a plurality of pixels PX in the display area DA. Here, the pixel represents the minimum unit which can be individually controlled in accordance with a pixel signal, and is provided, for example, in an area which includes a switching element arranged at the intersection of a scanning line and a signal line which will be described later. The pixels PX are arranged in a matrix in the first direction X and the second direction Y.

Further, the display panel PNL includes a plurality of scanning lines G (G1 to Gn), a plurality of signal lines S (S1 to Sm), a common electrode CE, etc., in the display area DA. The scanning lines G extend in the first direction X and are arranged in the second direction Y. The signal lines S extends in the second direction Y and are arranged in the first direction X. The scanning lines G and the signal lines S do not necessarily extend linearly and may be partially bent. The common electrode CE is arranged over a plurality of pixels PX.

The scanning lines G, the signal lines S and the common electrode CE are drawn out to the non-display area NDA. In the non-display area NDA, the scanning lines G are connected to the scanning line driver GD, the signal lines S are connected to the signal line driver SD, and the common electrode CE is connected to the common electrode driver CD. The signal line driver SD, the scanning line driver GD and the common electrode driver CD may be formed on the first substrate SUB1 or may be partially or entirely incorporated in the IC chip I1 shown in FIG. 1.

Each pixel PX includes a switching element SW, a pixel electrode PE, the common electrode CE, a liquid crystal layer LC, etc. The switching element SW is formed of a thin film transistor (TFT), for example, and is electrically connected to the scanning line G and the signal line S. More specifically, the switching element SW includes a gate electrode WG, a source electrode WS and a drain electrode WD. The gate electrode WG is electrically connected to the scanning line G. In the example illustrated, an electrode which is electrically connected to the signal line S is referred to as the source electrode WS, and an electrode which is electrically connected to the pixel electrode PE is referred to as the drain electrode WD.

Each scanning line G is connected to the switching electrodes SW of the pixels PX which are arranged in the first direction X. Each signal line S is connected to the switching electrodes SW of the pixels PX which are arranged in the second direction Y. Each pixel electrode PE is opposed to the common electrode CE and drives the liquid crystal layer LC by an electric field which is generated between the pixel electrode PE and the common electrode CE. Storage capacitance CS is formed between the common electrode CE and the pixel electrode PE, for example.

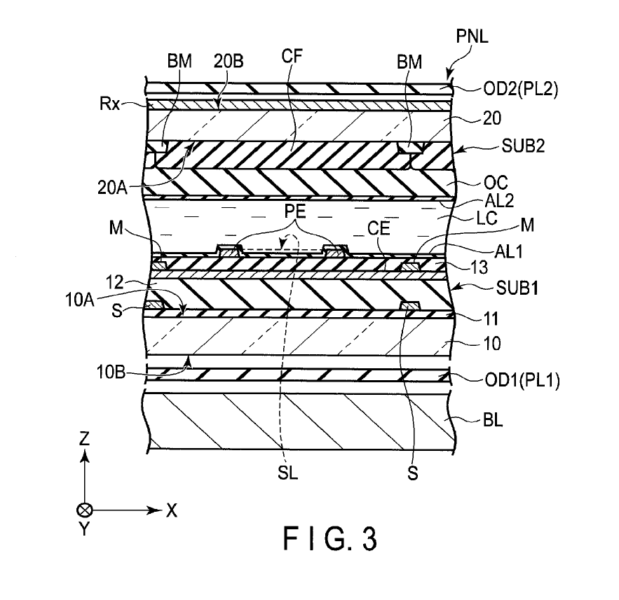

FIG. 3 is a sectional view showing the structure of the display area DA of the display panel PNL shown in FIG. 1. This is a sectional view in the X-Z plane defined by the first direction X and the third direction Z. The third direction Z corresponds to a direction from the first substrate SUB1 to the second substrate SUB2.

The illustrated display panel PNL has a structure conforming to a display mode which mainly uses a lateral electric field substantially parallel to a substrate surface. The display panel PNL may have a structure conforming to a display mode which uses a longitudinal electric field which is perpendicular to a substrate surface, a display mode which uses an oblique electric field which is inclined with respect to a substrate surface, or a display mode which uses a combination thereof. In the display mode which uses the lateral electric field, for example, the display panel PNL can have such a structure that both the pixel electrode PE and the common electrode CE are provided on one of the first substrate SUB1 and the second substrate SUB1. In the display mode which uses the longitudinal electric field or the oblique electric field, for example, the display panel PNL can have such a structure that one of the pixel electrode PE and the common electrode CE is provided on the first substrate SUB1, and the other one of the pixel electrode PE and the common electrode CE is provided on the second substrate SUB2. The substrate surface here is a surface parallel to the X-Y plane.

The first substrate SUB1 is composed of a first basement 10. The first basement 10 is formed of an insulating material such as glass or resin. The first basement 10 has a surface 10A which is opposed to the second substrate SUB2 and a surface 10B which is opposite to the surface 10A. The first substrate SUB1 includes the signal line S, the common electrode CE, a metal layer M, the pixel electrode PE, a first insulating layer 11, a second insulating layer 12, a third insulating layer 13, a first alignment film AL1, etc., on the surface 10A side of the first basement 10. Here, the switching element and the scanning line, and various insulating layers interposed between them, etc., are not shown in the drawing.

The first insulating layer 11 is located above the first basement 10. The scanning line and a semiconductor layer of the switching element which are not shown in the drawing are located between the first basement 10 and the first insulating layer 11. The signal line S is located above the first insulating layer 11. The second insulating layer 12 is located above the signal line S and the first insulating layer 11. The common electrode CE is located above the second insulating layer 12. The metal layer M contacts the common electrode CE directly above the signal line S. The metal layer M is located above the common electrode CE in the example illustrated but may be located between the common electrode CE and the second insulating layer 12. The third insulating layer 13 is located above the common electrode CE and the metal layer M. The pixel electrode PE is located above the third insulating layer 13. The pixel electrode PE is opposed to the common electrode CE via the third insulating layer 13. Further, the pixel electrode PE has a slit SL at a position opposed to the common electrode CE. The first alignment film AL1 covers the pixel electrode PE and the third insulating layer 13.

The scanning line, the signal line S and the metal layer M are formed of a metal material such as molybdenum, tungsten, titanium or aluminum, and may have a single layer structure or a multilayer structure. The common electrode CE and the pixel electrode PE are formed of a transparent conductive material such as indium tin oxide (ITO) or indium zinc oxide (IZO). The first insulating layer 11 and the third insulating layer 13 are inorganic insulating layers, and the second insulating layer 12 is an organic insulating layer. For example, the scanning line is formed of a metal material including tungsten, and the signal line S is formed of a metal material including aluminum.

The structure of the first substrate SUB1 is not limited to the example illustrated, and the pixel electrode PE may be located between the second insulating layer 12 and the third insulating layer 13, and the common electrode CE may be located between the third insulating layer 13 and the first alignment film AL1. In this case, the pixel electrode PE has the shape of a flat plate with no slit, and the common electrode CE has a slit opposed to the pixel electrode PE. Alternatively, both the pixel electrode PE and the common electrode CE may have the shape of a comb and may be engaged with each other.

The second substrate SUB2 is composed of a second basement 20. The second basement 20 is formed of an insulating material such as glass or resin. The second basement 20 has a surface 20A which is opposed to the first substrate SUB1 and a surface 20B which is opposite to the surface 20A. The second substrate SUB2 includes a light-shielding layer BM, a color filter CF, an overcoat layer OC, a second alignment film AL2, etc., on the surface 20A side of the second basement 20.

The light-shielding layer BM and the color filter CF are located on one side of the second basement 20 which is opposed to the first substrate SUB1. The light-shielding layer BM partitions the pixels and is located directly above the signal lines S. The color filter CF is opposed to the pixel electrode PE and partially overlaps the light-shielding layer BM. The color filter CF includes a red color filter, a green color filter, a blue color filter, etc. The overcoat layer OC covers the color filter CF. The second alignment film AL2 covers the overcoat layer OC.

The color filter CF may be arranged on the first substrate SUB1. The color filter CF may include color filters corresponding to four or more colors. A pixel which shows white color may be provided with a white color filter or an uncolored resin material or may be provided with the overcoat layer OC without any color filter.

The detection electrode Rx is located on the surface 20B of the second basement 20. The detection electrode Rx may be formed of a conductive layer including metal or a transparent conductive material such as ITO or IZO, may have such a multilayer structure that a transparent conductive layer is disposed on a conductive layer including metal, or may be formed of a conductive organic material or a dispersoid of a conductive fine substance, etc.

A first optical element OD1 including a first polarizer PL1 is located between the first basement 10 and an illumination device BL. A second optical element OD2 including a second polarizer PL2 is located above the detection electrode Rx. The first optical element OD1 and the second optical element OD2 may include retardation films if necessary.

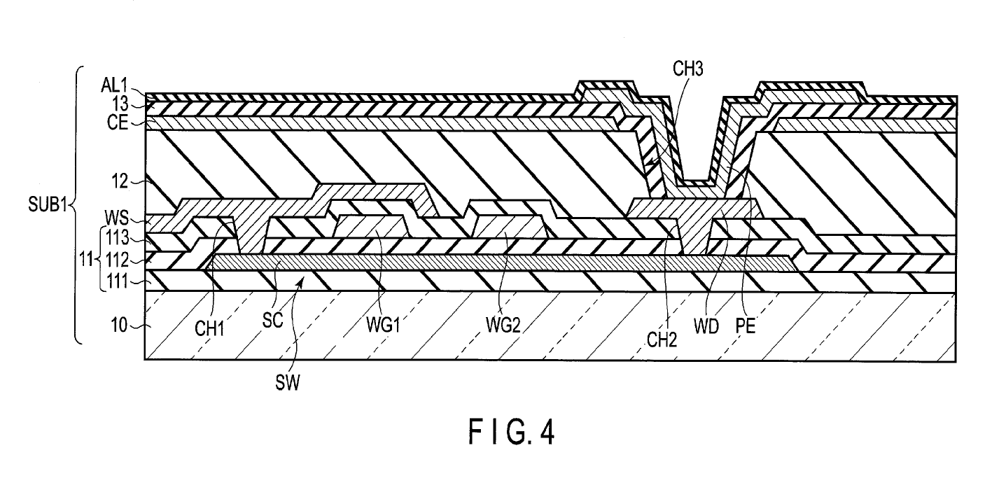

FIG. 4 is a sectional view showing the connection relationship between the switching element SW and the pixel electrode PE on the first substrate SUB1. A double-gate thin-film transistor is shown as the switching element SW, but the switching element SW may be a single-gate thin-film transistor.

A semiconductor layer SC which constitutes the switching element SW is formed on an inorganic insulating layer 111 as an undercoat layer and is covered with an inorganic insulating layer 112. Gate electrodes WG1 and WG2 are formed on the organic insulating layer 112 and are covered with the inorganic insulating layer 113. The source electrode WS and the drain electrode WD are formed on the inorganic insulating layer 113. The source electrode WS and the drain electrode WD contact the semiconductor layer SC through a contact hole CH1 and a contact hole CH2 which are provided in the inorganic insulating layer 111 and the inorganic insulating layer 112. The inorganic insulating layer 111, the inorganic insulating layer 112 and the inorganic insulating layer 113 correspond to the first insulating layer 11 shown in FIG. 3.

The second insulating layer 12 covers the source electrode WS and the drain electrode WD and is also formed on the inorganic insulating layer 113. In the example illustrated, a contact hole CH3 penetrating down to the drain electrode WD is formed in an area of the second insulating layer 12 which overlaps the contact hole CH2. The common electrode CE is formed on the second insulating layer 12 but is not formed in the contact hole CH3. The third insulating layer 13 covers the common electrode CE and is also formed on the second insulating layer 12. In the example illustrated, the third insulating layer 13 also covers the side surface of the contact hole CH3 but exposes at least part of the drain electrode WD. The pixel electrode PE is formed on the third insulating layer 13 and contacts the drain electrode WD via the contact hole CH3.

Next, an example of the structure of the sensor SS mounted on the display device DSP of the present embodiment will be described. The sensor SS which will be described below is a mutual-capacitive sensor, for example, and detects contact or approach of an object based on a change in the electrostatic capacitance between a pair of electrodes which are opposed to each other via a dielectric.

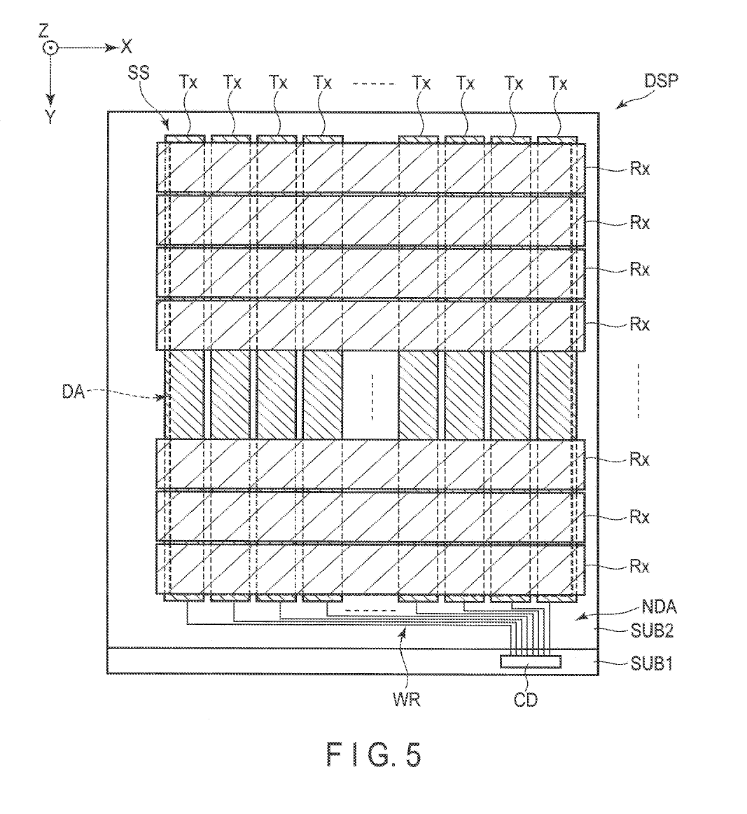

FIG. 5 is a plan view showing an example of the structure of the sensor SS.

In the example illustrated, the sensor SS includes sensor drive electrodes Tx and the detection electrodes Rx. In the example illustrated, the sensor drive electrodes Tx correspond to portions shaded with falling diagonal lines and are provided on the first substrate SUB1. The detection electrodes Rx correspond to portions shaded with rising diagonal lines and are provided on the second substrate SUB2. The sensor drive electrodes Tx and the detection electrodes Rx intersect each other in the X-Y plane. The detection electrodes Rx are opposed to the sensor drive electrodes Tx in the third direction Z.

The sensor drive electrodes Tx and the detection electrodes Rx are located in the display area DA and are partially elongated in the non-display area NDA. In the example illustrated, the sensor drive electrodes Tx are formed into strips elongated in the second direction Y and are arranged at intervals in the first direction X. The detection electrodes Rx are elongated in the first direction X and are arranged at intervals in the second direction Y. The detection electrodes Rx are connected to pads provided on the first substrate SUB1 and are electrically connected to the detection circuit RC via wiring lines as described above with reference to FIG. 1. The sensor drive electrodes Tx are electrically connected to the common electrode driver CD via wiring lines WR. The numbers, sizes and shapes of the sensor drive electrodes Tx and detection electrodes Rx are not particularly limited but may be variously changed.

The sensor drive electrode Tx includes the common electrode CE, and has a function of generating an electric field between itself and the pixel electrode PE and also a function of detecting the position of an object by generating capacitance between itself and the detection electrode Rx.

The common electrode driver CD supplies a common drive signal to the sensor drive electrode Tx including the common electrode CE in a display drive mode of displaying an image on the display area DA. Further, the common electrode driver CD supplies a sensor drive signal to the sensor drive electrode Tx in a sensing drive mode of performing sensing. The detection electrode Rx outputs a sensor signal necessary for sensing (that is, a signal based on a change in the interelectrode capacitance between the sensor drive electrode Tx and the detection electrode Rx) when the sensor drive signal is supplied to the sensor drive electrode Tx. A detection signal output from the detection electrode Rx is input to the detection circuit RC shown in FIG. 1.

The sensor SS in the above-described structural example is not limited to a mutual-capacitive sensor which detects an object based on a change in the electrostatic capacitance between a pair of electrodes (the electrostatic capacitance between the sensor drive electrode Tx and the detection electrode Rx in the above-described example) and may be a self-capacitive sensor which detects an object based on a change in the electrostatic capacitance of the detection electrode Rx.

FIG. 6 is a plan view showing an example of the structure in the vicinity of the terminal RT1 of the detection electrode Rx1 shown in FIG. 1.

The detection electrode Rx1 includes the terminal RT1, the detector RS and a connection line CW. In the example illustrated, the terminal RT1 has the shape of a circular ring. The terminal RT1 is connected to the detector RS via the connection line CW. The detector RS is formed of meshed fine metal lines MS. In the example illustrated, the contact hole V1 is located inside the terminal RT1. At least part of the contact hole V1 needs to overlap the terminal RT1. Further, the metal lines MS do not necessarily have the illustrated shape and may have another shape such as the shape of a wave, the shape of saw teeth or the shape of a sinusoidal wave.

FIG. 7 is an enlarged view of the pad P1 shown in FIG. 1.

For example, the pad P1 has an octagon shape. The pad P1 may have a polygonal shape other than an octagon shape, may have a circular shape or an elliptical shape, or may have a shape consisting of straight lines and curved lines. The pad P1 and the wiring line W1 are formed of a single member in the example illustrated but may be formed of a plurality of members.

The pad P1 has a hole VB. In the example illustrated, the pad P1 has two slits ST between which the hole VB is sandwiched. Accordingly, for example, even if the sealant SE and the pad P1 overlap each other, when the sealant SE is cured by ultraviolet irradiation, ultraviolet light reaches the sealant SE through the slits ST, and therefore the sealant SE can be reliably cured. In the example shown in FIG. 7(A), the slits ST are away from the hole VB. In the example shown in FIG. 7(B), the slits ST are continuous with the hole VB. It is possible to provide one slit ST or three or more slits ST or omit the slit ST. Further, the slit ST does not necessarily have the illustrated shape and may have another shape.

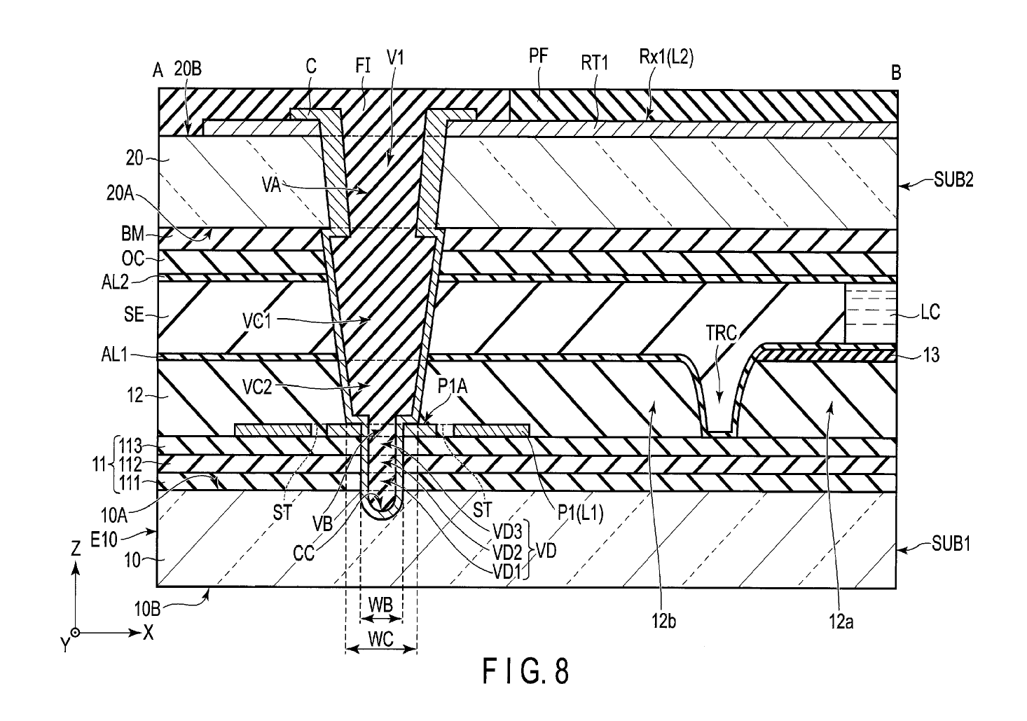

FIG. 8 is a sectional view of the display panel PNL taken along line A-B shown in FIG. 1. The drawing only shows the main portions necessary for explanation.

The first substrate SUB1 includes the pad P1 (the first conductive layer L1), the first insulating layer 11, the second insulating layer 12, the third insulating layer 13, the first alignment film AL1, etc., on the surface 10A side of the first basement 10.

The first insulating layer 11 has such a layered structure that the inorganic insulating layer 111, the inorganic insulating layer 112 and the inorganic insulating layer 113 are stacked in this order in the third direction Z. In the example illustrated, the first insulating layer 11 contacts the entire surface 10A. As described above, the inorganic insulating layer 111 is located below the semiconductor layer SC of the switching element SW in the display area DA. The inorganic insulating layer 112 is located above the semiconductor layer SC of the switching element SW and contacts the semiconductor layer SC in the display area DA. The inorganic insulating layer 113 is located above and contacts the gate electrode WG of the switching element SW and the scanning line G connected to the gate electrode WG in the display area DA.

The pad P1 is formed on the first insulating layer 11 and is covered with the second insulating layer 12. In the example illustrated, the inorganic insulating layer 113 of the first insulating layer 11 contacts the second insulating layer 12. For example, the pad P1 is formed of the same material as that of the signal line S shown in FIG. 3. More specifically, the pad P1 has a layered structure of titanium (Ti), aluminum (Al) and titanium (Ti) in this order.

The pad P1 may also be formed of the same material as that of the scanning line G shown in FIG. 1.

However, if the scanning line G is formed of a material including tungsten as described above, the pad P1 should preferably be formed of a material different from that of the scanning line G. Since the melting point of tungsten is higher than that of aluminum, when the hole VB is formed, for example, by laser beam irradiation, the hole VB may be formed into a shape unsuitable for electrically connecting a connecting material C and the pad P1 in some cases. Therefore, if the scanning line G is formed of a material including tungsten and the signal line S does not include tungsten and is formed of a metal material having a relatively low melting point such as aluminum, for example, the pad P1 should preferably be formed of the same material as that of the signal line S.

The second insulating layer 12 covers the pad P1 and is also provided on the inorganic insulating layer 113. As described above, the second insulating layer 12 is located above and contacts the source electrode WS and the drain electrode WD of the switching element SW and the signal line S connected to the source electrode WS. In the example illustrated, the second insulating layer 12 is provided from the display area DA to an edge E10 of the first basement 10. For example, the second insulating layer 12 has a groove TRC which exposes part of the inorganic insulating layer 113 between the display area DA and the pad P1. The groove TRC divides the second insulating layer 12 into a second insulating layer 12a located on the display area DA side and a second insulating layer 12b located on the non-display area NDA side. When the groove TRC is provided, moisture will be prevented from entering from the non-display area NDA side to the display area DA side.

The third insulating layer 13 is located above the second insulating layer 12. In the example illustrated, the third insulating layer 13 is provided on the second insulating layer 12a but is not provided on the second insulating layer 12b. As described above, the third insulating layer 13 is located above and contacts the common electrode CE in the display area DA. The second insulating layer 12 and the third insulating layer 13 are covered with the first alignment film AL1. In the example illustrated, the first alignment film AL1 contacts the inorganic insulating layer 113 in the groove TRC.

The second substrate SUB2 includes the light-shielding layer BM, the overcoat layer OC, the second alignment film AL2, etc., which are formed of an organic material. Further, the second substrate SUB2 includes the detection electrode Rx1 (the second conductive layer L2) on the surface 20B of the second basement 20. The detection electrode Rx1 is covered with a protection material PF. The protection material PF is formed of an organic insulating material such as acrylic resin.

The sealant SE is located between the first substrate SUB1 and the second substrate SUB2 and attaches the first substrate SUB1 and the second substrate SUB2 to each other. That is, the sealant SE contacts the first alignment film AL1 and the second alignment film AL2. In the example illustrated, the sealant SE is provided throughout an area located on the edge E10 side from the liquid crystal layer LC in the first direction X. The sealant SE is formed of an organic material. The liquid crystal layer LC is located on the inner side from the sealant SE, that is, on the display area DA side between the first substrate SUB1 and the second substrate SUB2.

The contact hole V1 is formed in an area in which the pad P1 and the detection electrode Rx1 overlap each other. The contact hole V1 includes a hole VA which penetrates the second basement 20, the hole VB which penetrates the pad P1, a hole VC1 which penetrates the sealant SE, a hole VC2 which penetrates the second insulating layer 12, a hole VD which penetrates the first insulating layer 11 and a concavity CC which is formed in the first basement 10. In the example illustrated, the contact hole V1 also penetrates the terminal RT of the detection electrode Rx. The concavity CC, the hole VD, the hole VB, the hole VC2, the hole VC1 and the hole VA are arranged in this order in the third direction Z and are located on the same line in the third direction Z. In other words, the pad P1 is opposed to the holes VA, VC1 and VC2.

For example, the hole VA has a tapered cross-section. That is, the width of the hole VA on the surface 20B is greater than the width of the hole VA on the surface 20A. A width in the explanation of FIG. 8 corresponds to a dimension in the first direction X.

In the example illustrated, the hole VC1 penetrates the sealant SE and also penetrates the light-shielding layer BM, the overcoat layer OC, the second alignment film AL2 and the first alignment film AL1. In the example illustrated, the width of the hole VC1 on the surface 20A is greater than the width of the hole VA.

The hole VC2 exposes part of an upper surface P1A of the pad P1. In the example illustrated, the hole VC2 is located between the two slits ST in the first direction X. A width WC of the hole VC on the upper surface P1A is greater than a width WB of the hole VB.

The hole VD includes a hole VD1 which penetrates the inorganic insulating layer 111, a hole VD2 which penetrates the inorganic insulating layer 112 and a hole VD3 which penetrates the inorganic insulating layer 113. In the example illustrated, the width of the hole VD is substantially equal to the width of the hole VB.

The connecting material C is provided in the contact hole V1 and electrically connects the detection electrode Rx1 and the pad P1. The connecting material C is formed of a conductive material including a metal material such as silver, for example. The connecting material C should preferably include fine particles of a metal material having a particle diameter of the order of several nanometers to several tens of nanometers. In the example illustrated, the connecting material C has a hollow, and the hollow is filled with an insulating filling material FI. The filling material FI covers part of the terminal RT1 on the second substrate SUB2. The hollow may be filled with a conductive filling material instead. Alternatively, the contact hole V1 may be filled with the connecting material C.

The connecting material C contacts at least the detection electrode Rx1 and the pad P1. More specifically, the connecting material C contacts the terminal RT1 on the surface 20B of the second basement 20. In the example illustrated, the connecting material C overlaps the terminal RT1 in the third direction Z. In the hole VA, the connecting material C contacts the second basement 20. In the hole VC1, the connecting material C contacts the sealant SE and also contacts the second basement 20, the light-shielding layer BM, the overcoat layer OC, the second alignment film AL2 and the first alignment film AL1. In the hole VC2, the connecting material C contacts the second insulating layer 12 and the upper surface P1A of the pad P1. In the hole VB, the connecting material C contacts the side surface of the pad P1. In the hole VD, the connecting material C contacts the inorganic insulating layers 111, 112 and 113. In the concavity CC, the connecting material C contacts the first basement 10.

The connecting material C may contact part of the pad P1 in the contact hole V1. Further, the pad P1 may not have the hole VB. In that case, the connecting material C contacts the upper surface P1A of the pad p1.

According to the display device DSP equipped with the sensor SS, the detection electrode Rx provided on the second substrate SUB2 is connected to the pad P provided on the first substrate SUB1 by the connecting material C provided in the contact hole V. Therefore, it is no longer necessary to mount a wiring substrate which connects the detection electrode Rx and the detection circuit RC on the second substrate SUB2. That is, the wiring substrate SUB3 mounted on the first substrate SUB1 forms a transmission channel for transmitting a signal necessary for displaying an image on the display panel PNL and also forms a transmission channel for transmitting a signal between the detection electrode Rx and the detection circuit RC. Therefore, the number of wiring substrates can be reduced as compared to a structural example which requires a wiring substrate other than the wiring substrate SUB3. Further, since the space for connecting a wiring substrate to the second substrate SUB2 is no longer necessary, the non-display area of the display panel PNL, in particular, the width of the side on which the wiring substrate SUB3 is mounted can be reduced. Accordingly, the frame can be narrowed.

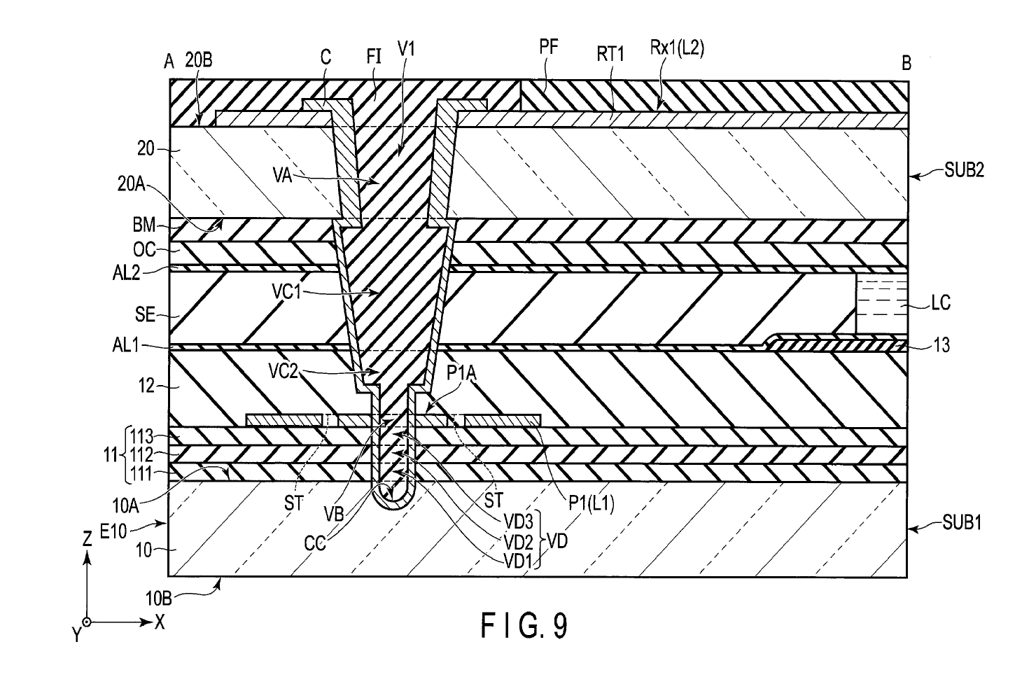

Modifications of the present embodiment will be described with reference to FIGS. 9 to 28.

### First Modification

FIG. 9 shows the first modification of the display device DSP according to the present embodiment. The first modification differs from the example shown in FIG. 8 in that the second insulating layer 12 does not have the groove TRC. That is, the second insulating layer 12 is continuously provided from the display area DA to the edge E10. The same effect produced from the example shown in FIG. 8 can be produced from the first modification.

### Second Modification

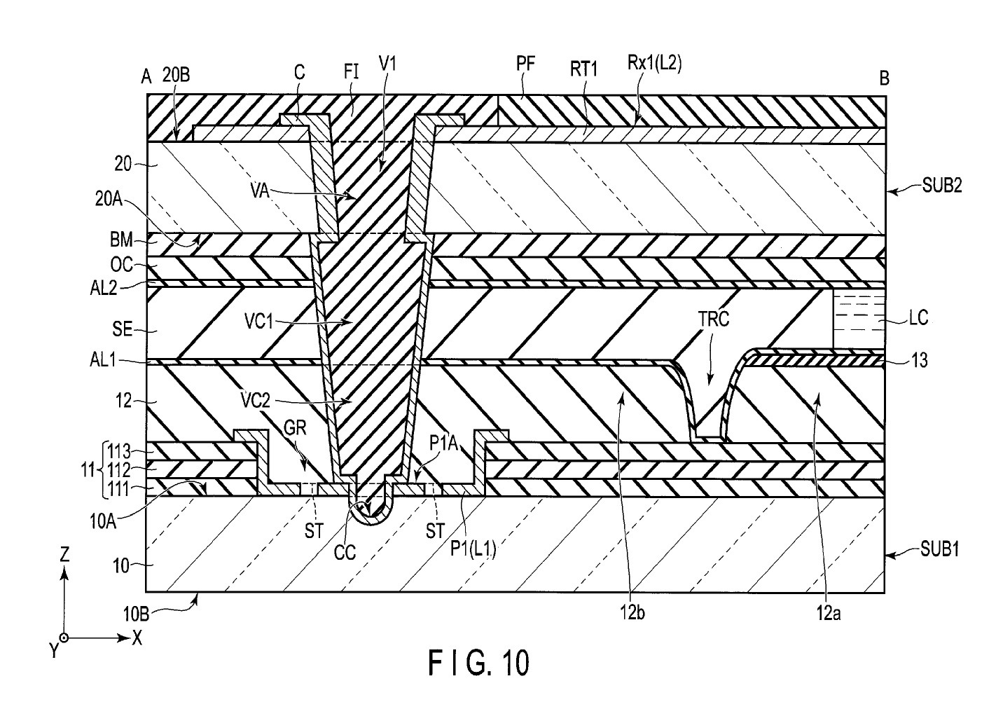

FIG. 10 shows the second modification of the display device DSP according to the present embodiment. The second modification differs from the example shown in FIG. 8 in that the pad P1 is provided on the surface 10A.

The first insulating layer 11 has a recess GR which penetrates the inorganic insulating layers 113, 112 and 111 down to the surface 10A. The pad P1 contacts the surface 10A in the recess GR. In the example illustrated, the pad P1 contacts the inorganic insulating layers 111, 112 and 113 in the recess GR and is also formed on the inorganic insulating layer 113. The second insulating layer 12 is provided in the recess GR and contacts the pad P1. The contact hole V1 does not include the hole VD but include the holes VA, VC1, VC2 and VB and the concavity CC. The same effect produced from the example shown in FIG. 8 can be produced from the present modification.

### Third Modification

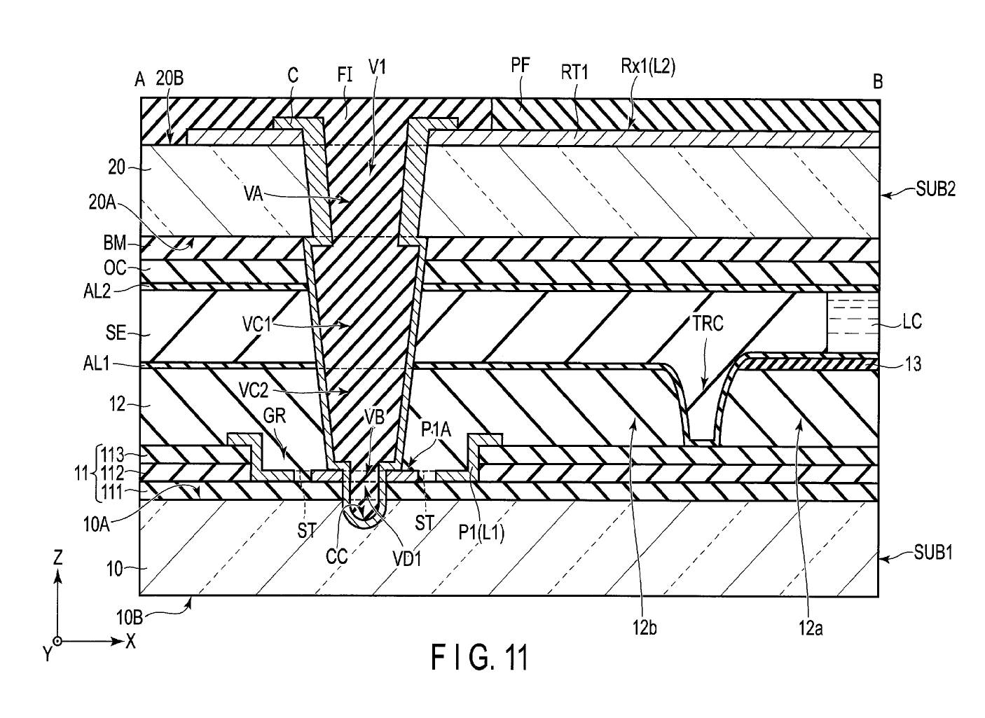

FIG. 11 shows the third modification of the display device DSP according to the present embodiment. The third embodiment differs from the example shown in FIG. 8 in that the pad P1 is provided on the inorganic insulating layer 111.

The first insulating layer 11 has the recess GR which penetrates the inorganic insulating layers 113 and 112 down to the inorganic insulating surface 111. The pad P1 contacts the inorganic insulating layer 111 in the recess GR. In the example illustrated, the pad P1 contacts the inorganic insulating layers 112 and 113 in the recess GR and is also formed on the inorganic insulating layer 113. The contact hole V1 includes the holes VA, VC1, VC2, VB and VD1 and the concavity CC. The same effect produced from the example shown in

FIG. 8 can be produced from the present modification. In the example illustrated, only the inorganic insulating layer 111 of the first insulating layer 11 is provided between the first basement 10 and the pad P1. However, only the inorganic insulating layer 112 may be provided or only the inorganic insulating layer 113 may be provided in place of the inorganic insulating layer 111.

### Fourth Modification

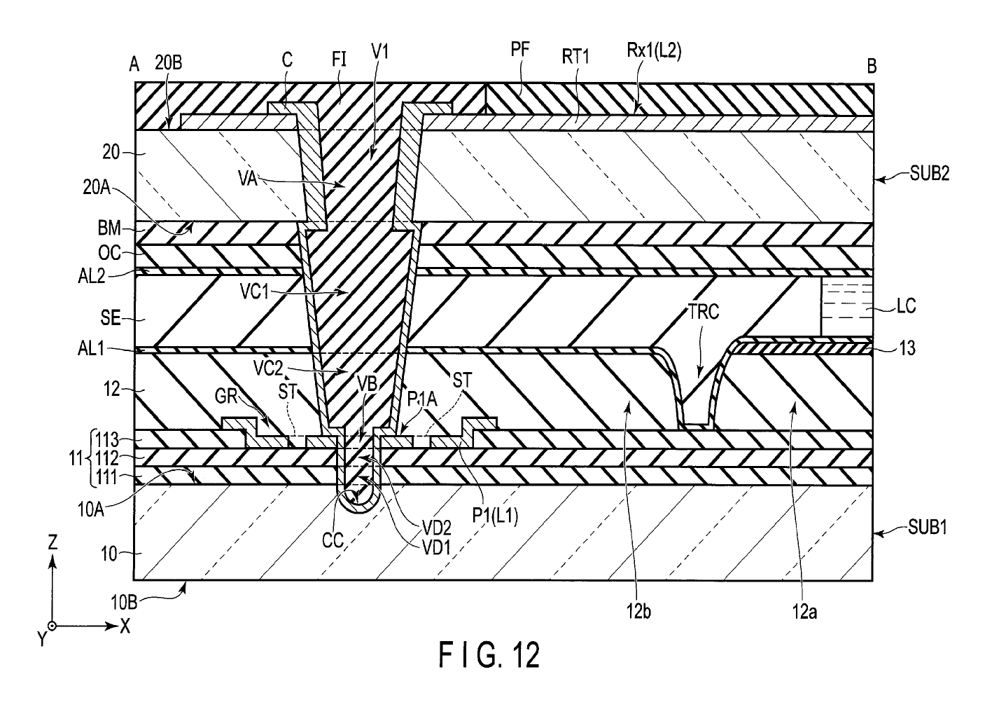

FIG. 12 shows the fourth modification of the display device DSP according to the present embodiment. The fourth modification differs from the example shown in FIG. 8 in that the pad P1 is provided on the inorganic insulating layer 112.

The first insulating layer 11 has the recess GR which penetrates the inorganic insulating layer 113 down to the inorganic insulating layer 112. The pad P1 contacts the inorganic insulating layer 112 in the recess GR. In the example illustrated, the pad P1 contacts the inorganic insulating layer 113 in the recess GR and is also formed on the inorganic insulating layer 113. The contact hole V1 includes the holes VA, VC1, VC2, VB, VD2 and VD1 and the concavity CC. The same effect produced from the example shown in FIG. 8 can be produced from the present modification. In the example illustrated, the two inorganic insulating layers 111 and 112 of the first insulating layer 11 are provided between the first basement 10 and the pad P1, but two layers are not limited to this combination, and any two layers of the inorganic insulating layers 111 to 113 included in the first insulating layer 11 may be provided.

### Fifth Embodiment

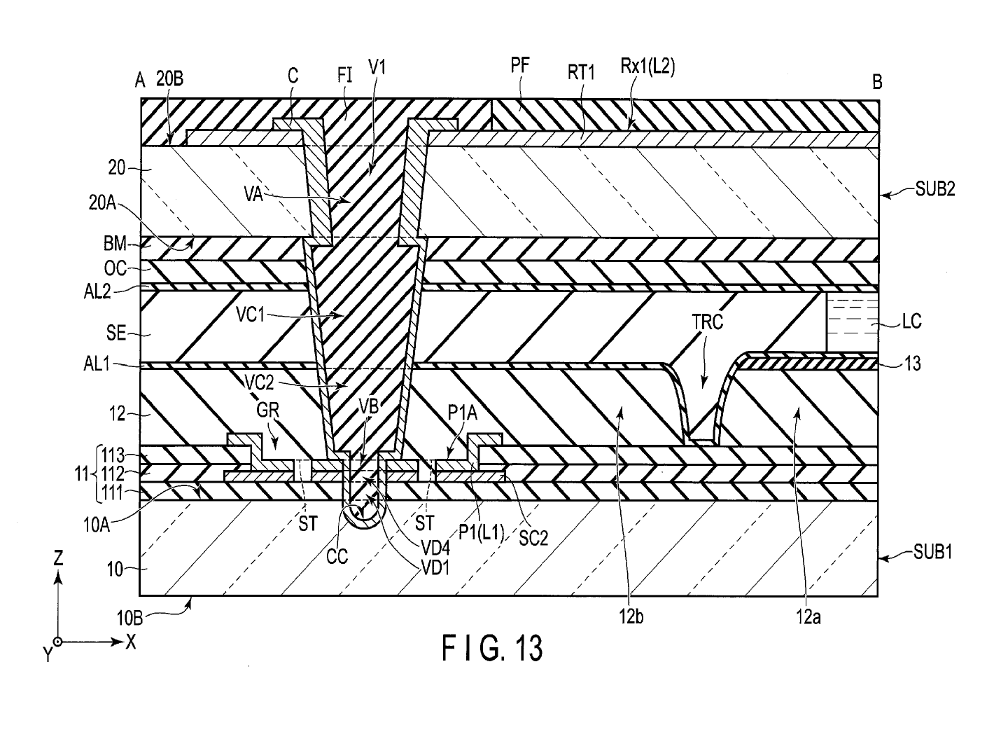

FIG. 13 shows the fifth modification of the display device DSP according to the present embodiment. The fifth modification differs from the structural example shown in FIG. 8 in that the pad P1 is provided on a semiconductor layer SC2.

The semiconductor layer SC2 is located directly below the pad P1 and between the inorganic insulating layer 111 and the inorganic insulating layer 112. For example, the shape of the semiconductor layer SC2 is substantially equal to the shape of the pad P1 in a plan view. The first insulating layer 11 has the recess GR which penetrates the inorganic insulating layers 113 and 112 down to the semiconductor layer SC2. The pad P1 contacts the semiconductor layer SC2 in the recess GR. In the example illustrated, the pad P1 contacts the inorganic insulating layers 112 and 113 in the recess GR and is also formed on the inorganic insulating layer 113. The semiconductor layer SC2 and the semiconductor layer SC of the switching element SW arranged in the display area DA can be formed in the same manufacturing process and can be formed of the same material. The slits ST penetrate the pad P1 and the semiconductor layer SC2.

The contact hole V1 includes a hole VD4 which penetrates the semiconductor layer SC2, in addition to the holes VA, VC1, VC2, VB and VD1 and the concavity CC. The hole VD4 is continuous with the hole VB and the hole VD1. In the example illustrated, the connecting material C contacts the semiconductor layer SC2 in the hole VD4.

The same effect produced from the example shown in FIG. 8 can be produced from the present modification. Further, since the pad P1 contacts the semiconductor layer SC2 and is electrically connected to the semiconductor layer SC2, when the semiconductor layer SC2 contacts the connecting material C in the contact hole V1, the contact area of the pad P1 and the connecting material C can be substantively increased.

### Sixth Modification

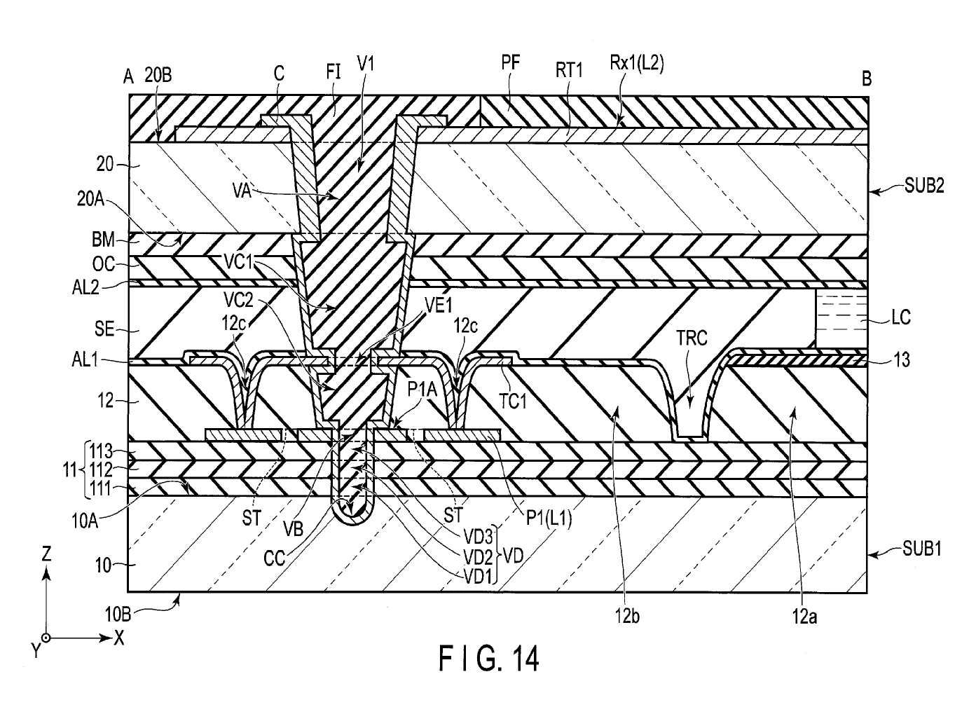

FIG. 14 shows the sixth modification of the display device DSP according to the present embodiment. The sixth modification differs from the example shown in FIG. 8 in that a transparent conductive layer TC1 is provided on the second insulating layer 12.

The transparent conductive layer TC1 is located directly above the pad P1 via the second insulating layer 12. In the example illustrated, the transparent conductive layer TC1 is covered with the first alignment film AL1. The transparent conductive layer TC1 is formed of ITO or IZO, for example. This transparent conductive layer TC1 can be formed simultaneously with the common electrode CE or the pixel electrode PE in the display area DA, for example. The second insulating layer 12 has a groove 12c which exposes part of the pad P1. The transparent conductive layer TC1 contacts the pad P1 in the groove 12c. Accordingly, the transparent conductive layer TC1 and the pad P1 are electrically connected to each other.

The contact hole V1 includes a hole VE1 which penetrates the transparent conductive layer TC1, in addition to the holes VA, VC1, VC2, VB and VD and the concavity CC. The hole VE1 is continuous with the hole VC1 and the hole VC2. In the example illustrated, the width of the hole VE1 is less than the widths of the holes VC1 and VC2. Here, the widths correspond to a dimension in the first direction X. The connecting material C contacts the light-shielding layer BM, the overcoat layer OC, the second alignment film AL2, the sealant SE and the first alignment film AL1 and also contacts the transparent conductive layer TC1 in the hole VC1. Further, the connecting material C contacts the second insulating layer 12 and the pad 31 and also contacts the transparent conductive layer TC1 in the hole VC2. In the example illustrated, the connecting material C also contacts the transparent conductive layer TC1 in the hole VE1.

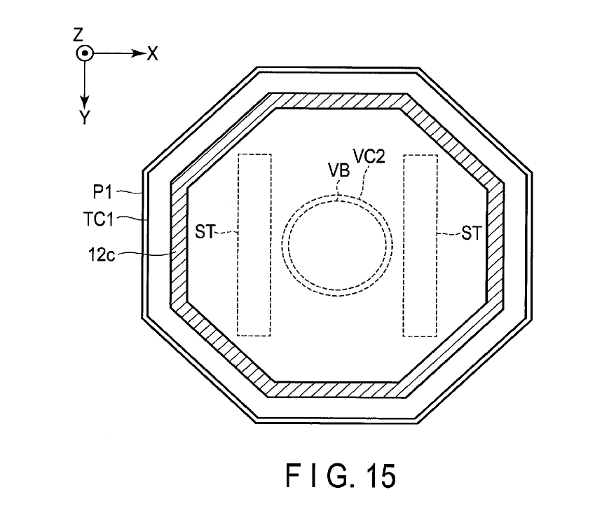

FIG. 15 is a plan view showing the positional relationship of the groove 12c shown in FIG. 14 to the pad P1 and the transparent conductive layer TC1. For example, the transparent conductive layer TC1 and the pad P1 have about the same size and shape. In the example illustrated, the groove 12c has the shape of a substantially octagonal ring along the outer edges of the pad P1 as shown by diagonal lines in the drawing and surrounds the hole VB, the hole VC and the slits ST. The groove 12c entirely overlaps the pad P1 and the transparent conductive layer TC1. The groove 12c may have the shape of a circular ring instead. Further, the groove 12c may not have the shape of a ring as will be described later.

The same effect produced from the example shown in FIG. 8 can be produced from the present modification. Further, since the transparent conductive layer TC1 contacts the pad P1 in the groove 12c and is electrically connected to the pad P1, when the transparent conductive layer TC1 contacts the connecting material C in the contact hole V1, the contact area of the pad P1 and the connecting material C can be substantively increased.

### Seventh Modification

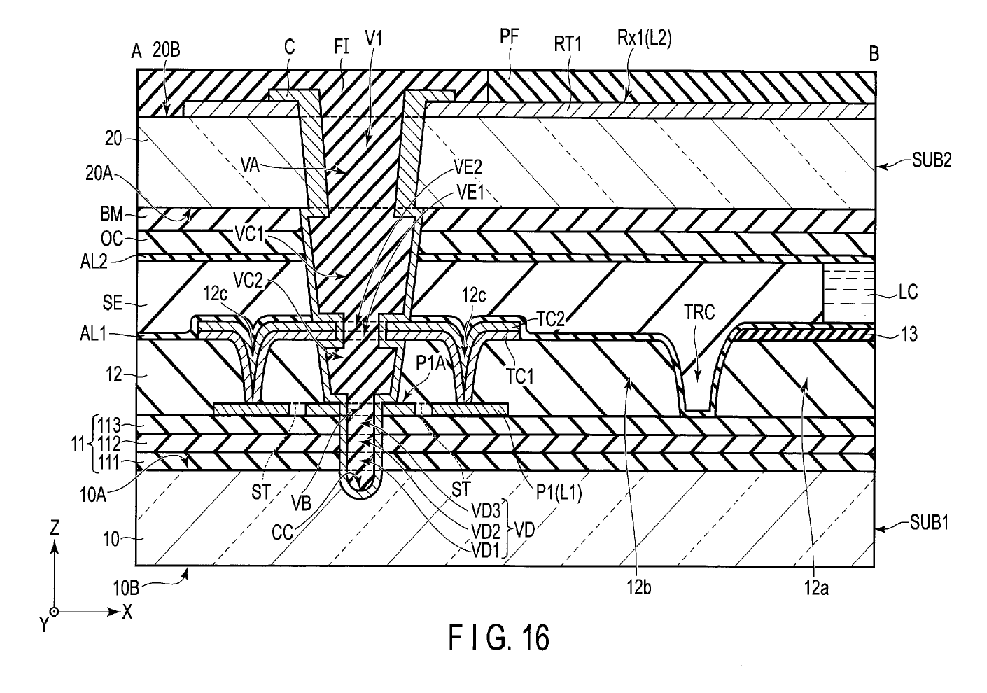

FIG. 16 shows the seventh modification of the display device DSP according to the present embodiment.

The seventh modification differs from the sixth modification in that a transparent conductive layer TC2 is provided directly above the transparent conductive layer TC1.

For example, the shape of the transparent conductive layer TC2 is the same as the shape of the transparent conductive layer TC1 shown in FIG. 15, and the entire lower surface of the transparent conductive layer TC2 contacts the transparent conductive layer TC1. In the example illustrated, the transparent conductive layer TC2 is covered with the first alignment film AL1. The transparent conductive layer TC2 is formed of ITO or IZO, for example. The transparent conductive layer TC1 can be formed simultaneously with the common electrode CE, for example, and the transparent conductive layer TC2 can be formed simultaneously with the pixel electrode PE, for example. The transparent conductive layer TC2 does not contact the pad P1 in the example illustrated but may contact the pad P1. That is, at least one of the transparent conductive layers TC1 and TC2 needs to contact the pad P1 and be electrically connected to the pad P1. The transparent conductive layers TC1 and TC2 can be regarded as a single transparent conductive layer having a greater thickness as compared to the pixel electrode PE or the common electrode PE if such a boundary surface as that shown in the drawing is not present.

The contact hole V1 includes a hole VE2 which penetrates the transparent conductive layer TC2. The hole VE2 is continuous with the hole VE1 and the hole VC2. In the example illustrated, the width of the hole VE2 is substantially equal to the width of the hole VE1. The connecting material C contacts the transparent conductive layer TC2 in the hole VC1 and contacts the transparent conductive layer TC1 in the hole VC2. In the example illustrated, the connecting material C contacts the transparent conductive layer TC2 in the hole VE2 and contacts the transparent conductive layer TC1 in the hole VE1. The same effect produced from the sixth modification can be produced from the present modification.

### Eighth Modification

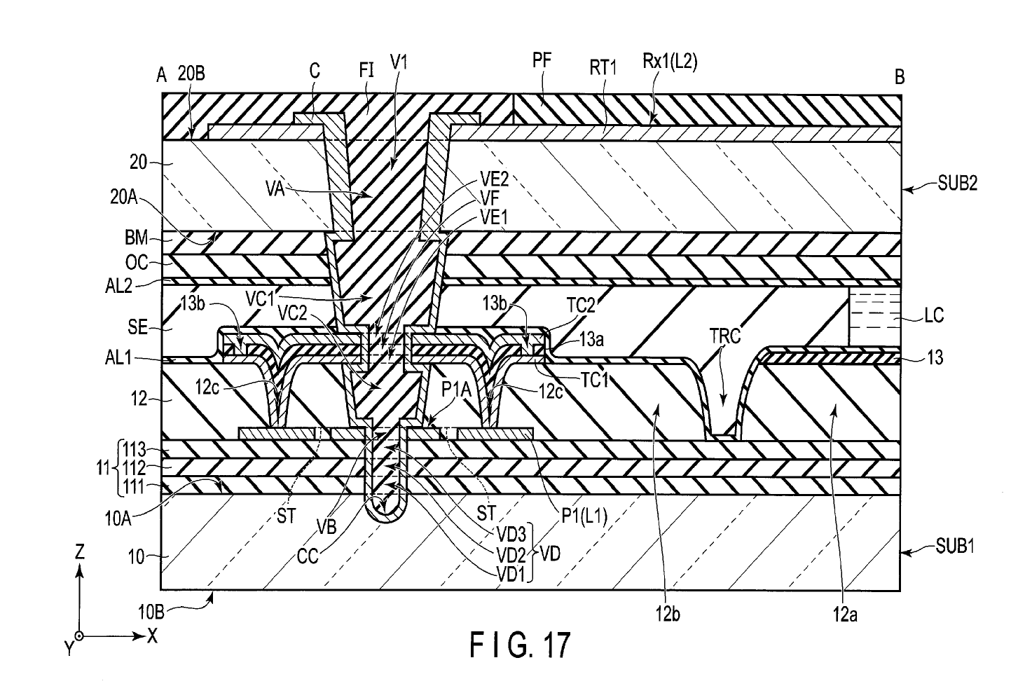

FIG. 17 shows the eighth modification of the display device DSP according to the present embodiment. The eighth modification differs from the seventh modification in that an inorganic insulating layer 13a is provided between the transparent conductive layer TC1 and the transparent conductive layer TC2.

The inorganic insulating layer 13a is formed of silicon nitride, for example. For example, the inorganic insulating layer 13a and the transparent conductive layer TC1 shown in FIG. 15 have the same shape. This inorganic insulating layer 13a can be formed simultaneously with the third insulating layer 13. As long as the inorganic insulating layer 13a is provided at least around the contact hole V1, the inorganic insulating layer 13a can be formed in any shape and is not necessarily formed in the shape shown in the drawing. For example, the area of the inorganic insulating layer 13a may be smaller than the areas of the transparent conductive layers TC1 and TC2. Alternatively, the area of the inorganic insulating layer 13a may be larger than the areas of the transparent conductive layers TC1 and TC2, and the inorganic insulating layer 13a may extend over the second insulating layer 12a.

In the example illustrated, the inorganic insulating layer 13a has a groove 13b which exposes part of the transparent conductive layer TC1. The transparent conductive layer TC1 and the transparent conductive layer TC2 contact each other in the groove 13b. Accordingly, the transparent conductive layer TC1 and the transparent conductive layer TC2 are electrically connected to each other.

The contact hole V1 includes a hole VF which penetrates the inorganic insulating layer 13a. The hole VF is continuous with the hole VE1 and the hole VE2. In the example illustrated, the width of the hole VF is substantially equal to the widths of the holes VE1 and VE2. The connecting material C contacts the transparent conductive layer TC2 in the holes VC1 and VE2 and contacts the transparent conductive layer TC1 in the holes VE1 and VC2. In the example illustrated, the connecting material C contacts the inorganic insulating layer 13a in the hole VF.

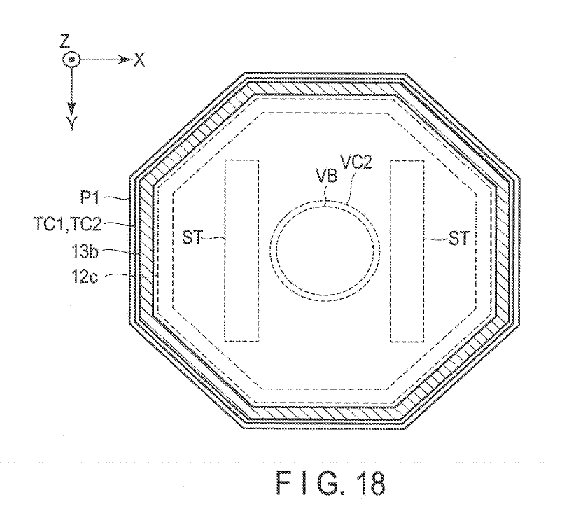

FIG. 18 is a plan view showing the positional relationship of the groove 13b shown in FIG. 17 to the transparent conductive layers TC1 and TC2.

For example, as shown by diagonal lines in the drawing, the groove 13b has the shape of a substantially octagonal ring along the outer edges of the transparent conductive layer TC1 and entirely overlaps the transparent conductive layer TC1 and the transparent conductive layer TC2. In the example illustrated, the groove 12c surrounds the hole VB and the hole VC, and the groove 13b surrounds the groove 12c. The groove 13b may overlap the groove 12c or may be located on the inner side from the groove 12c. Further, the groove 13b may have the shape of a circular ring. Alternatively, the groove 13b may not have the shape of a ring.

The same effect produced from the seventh modification can be produced from the present modification. Further, the inorganic insulating layer 13a formed of silicon nitride absorbs more laser light than an organic material of the sealant SE, etc., for example. Therefore, according of the present modification, when the contact hole V1 is formed by applying a laser beam from the second basement 20 to the first basement 10, for example, the laser beam is absorbed by the inorganic insulating layer 13a, and the intensity of the laser beam applied to the pad P1 will be reduced. Therefore, the pad P1 will be prevented from being melted by laser beam irradiation. Consequently, it is possible to prevent generation of a lump of a molten material caused by melting of the pad P1. If such a molten material is generated, the connecting material C may be prevented from contacting the pad P1 in some cases. Therefore, it is possible to increase the reliability of contact between the connecting material C and the pad P1 by preventing generation of a lump of a molten material.

### Ninth Modification

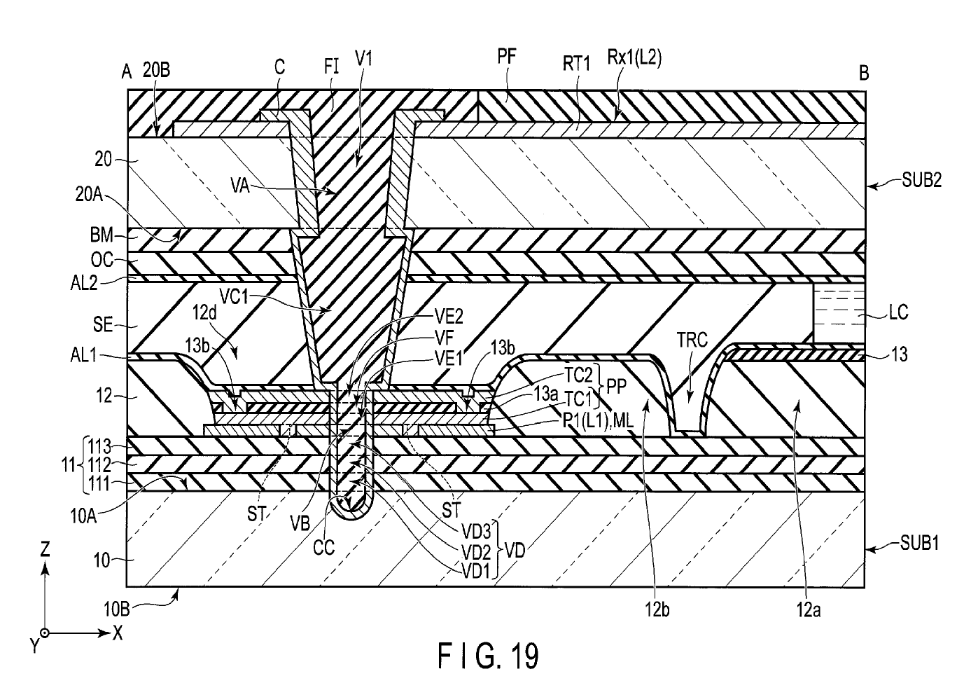

FIG. 19 shows the ninth modification of the display device DSP according to the present embodiment. The ninth modification differs from the eighth modification in that the second insulating layer 12 is not interposed between the transparent conductive layer TC1 and the pad P1.

The second insulating layer 12 has a groove 12d which exposes the pad P1. In the example illustrated, the outer edges of the pad P1 (both edges in the first direction X in the example illustrated) are covered with the second insulating layer 12. The transparent conductive layer TC1, the inorganic insulating layer 13a and the transparent conductive layer TC2 are formed within the groove 12d. The transparent conductive layer TC1 contacts substantially the entire upper surface P1A. In the example illustrated, the transparent conductive layer TC1 is also provided in the slits ST and contacts the inorganic insulating layer 113. The transparent conductive layer TC1, the inorganic insulating layer 13a and the transparent conductive layer TC2 may be partially located above the second insulating layer 12.

The contact hole V1 does not include the hole VC2. That is, the hole VE1 is continuous with the hole VF and the hole VB. In the example illustrated, the width of the hole VC1 is greater than the widths of the holes VE2, VF, VE1, VB and VD and the concavity CC. Here, the widths correspond to a dimension in the first direction X. In the example illustrated, the connecting material C contacts the transparent conductive layer TC2 in the holes VC1 and VE2, contacts the inorganic insulating layer 13a in the hole VF, contacts the transparent conductive layer TC1 in the hole VE1, and contacts the pad P1 in the hole VB.

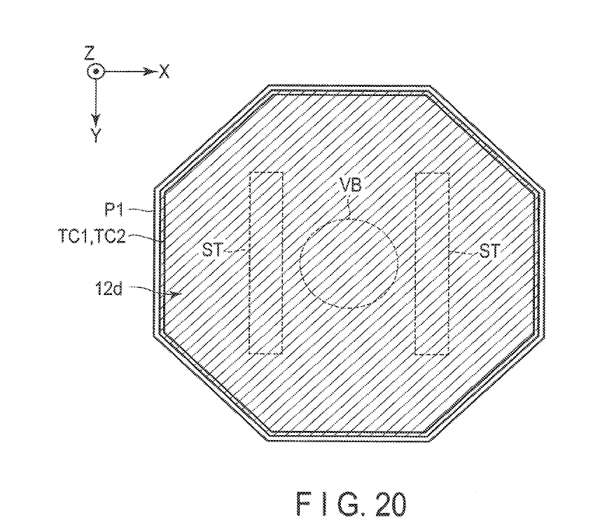

FIG. 20 is a plan view showing the positional relationship of the groove 12d shown in FIG. 19 to the pad P1 and the transparent conductive layers TC1 and TC2.

The transparent conductive layers TC1 and TC2 may have the same shape as that of the pad P1 and entirely overlap the pad P1 in the example illustrated. The groove 12d is formed in an area which substantially overlaps the pad P1 as shown by diagonal lines in the drawing. For example, the groove 12d has a substantially octagon shape which is slightly larger than the transparent conductive layers TC1 and TC2. The transparent conductive layers TC1 and TC2 are located within the groove 12d.

The same effect produced from the eighth modification can be produced from the present modification. In the present modification, the transparent conductive layers TC1 and TC2 can be regarded as a pad as will be described later. That is, it is possible to consider that the present modification includes a pad PP formed of the transparent conductive layers TC1 and TC2, the inorganic insulating layer 13a located between the transparent conductive layer TC1 and the transparent conductive layer TC2, and a metal layer ML located between the pad PP and the first basement 10, and the pad PP and the metal layer ML contact each other.

### Tenth Modification

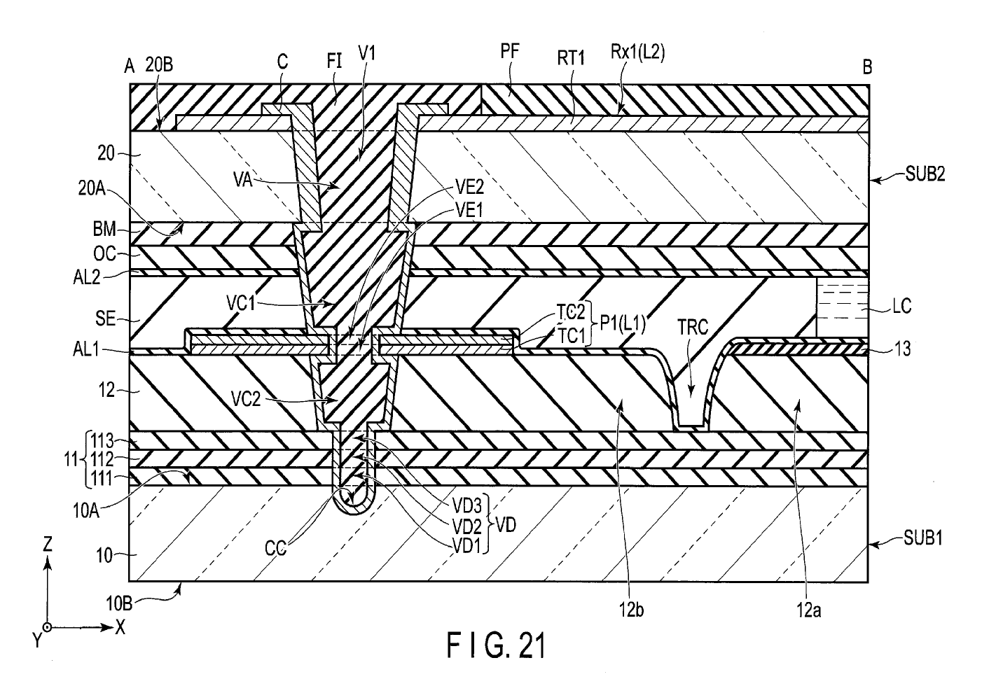

FIG. 21 shows the tenth modification of the display device DSP according to the present embodiment. The tenth modification differs from the example shown in FIG. 8 in that the pad P1 is located above the second insulating layer 12. That is, no conductive layer is interposed between the second conductive layer 12 and the first basement 10.

For example, the pad P1 is formed of the transparent conductive layer TC1 and the transparent conductive layer TC2. The entire lower surface of the transparent conductive layer TC1 contacts the second insulating layer 12. The entire lower surface of the transparent conductive layer TC2 contacts the transparent conductive layer TC1. The pad P1 has the same shape as that of the example shown in FIG. 7 but does not have the slits ST. The transparent conductive layer TC1 can be formed simultaneously with the common electrode CE, for example, and the transparent conductive layer TC2 can be formed simultaneously with the pixel electrode PE, for example. The pad P1 may be formed of one of the transparent conductive layers TC1 and TC2 instead.

The same effect produced from the example shown in FIG. 8 can be produced from the present modification. Further, according to the present modification, the pad P1 is formed of a transparent conductive material such as ITO or IZO. If the pad P1 is formed of this conductive material, when the contact hole V1 is formed by laser beam irradiation, for example, the pad P1 will be prevented from being melted, and this can prevent generation of a lump of a molten material caused by melting of the pad P1. If such a molten material is generated, the connecting material C may be prevented from contacting the pad P1 in some cases. Therefore, the reliability of contact between the connecting material C and the pad P1 can be increased by preventing generation of a lump of a molten material. Further, when the sealant SE is cured by ultraviolet irradiation, ultraviolet is transmitted through the pad P1, and therefore the sealant SE which overlaps the pad P1 can be reliably cured.

### Eleventh Modification

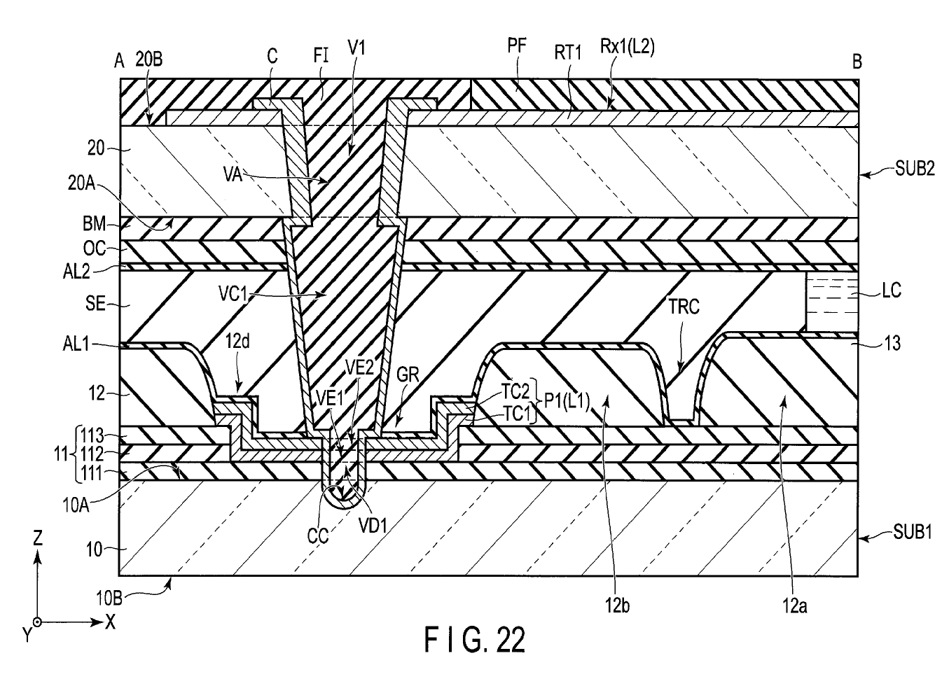

FIG. 22 shows the eleventh modification of the display device DSP according to the present embodiment. The eleventh modification differs from the tenth modification in that the second insulating layer 12 is not interposed between the pad P1 and the first insulating layer 11.

The second insulating layer 12 has the groove 12d which exposes the first insulating layer 11. The groove 12d has the same shape as that of the example shown in FIG. 20. The pad P1 is formed within the groove 12d. In the example illustrated, the pad P1 is formed on the inorganic insulating layer 111. That is, the first insulating layer 11 has the recess GR which penetrates the inorganic insulating layers 113 and 112 down to the inorganic insulating layer 111. In the recess GR, the pad P1 contacts the inorganic insulating layer 111. In the example illustrated, the pad P1 contacts the inorganic insulating layers 112 and 113 in the recess GR and is also formed on the inorganic insulating layer 113. The edges of the pad P1 contact the second insulating layer 12. Part of the pad P1 may be located above the second insulating layer 12.

The contact hole V1 does not include the hole VC2. That is, the hole VE1 is continuous with the hole VE2 and the hole VD1. In the example illustrated, the connecting material C contacts the transparent conductive layer TC2 in the holes VC1 and VE2 and contacts the transparent conductive layer TC1 in the hole VE1. The same effect produced from the tenth modification can be produced from the present modification.

### Twelfth Modification

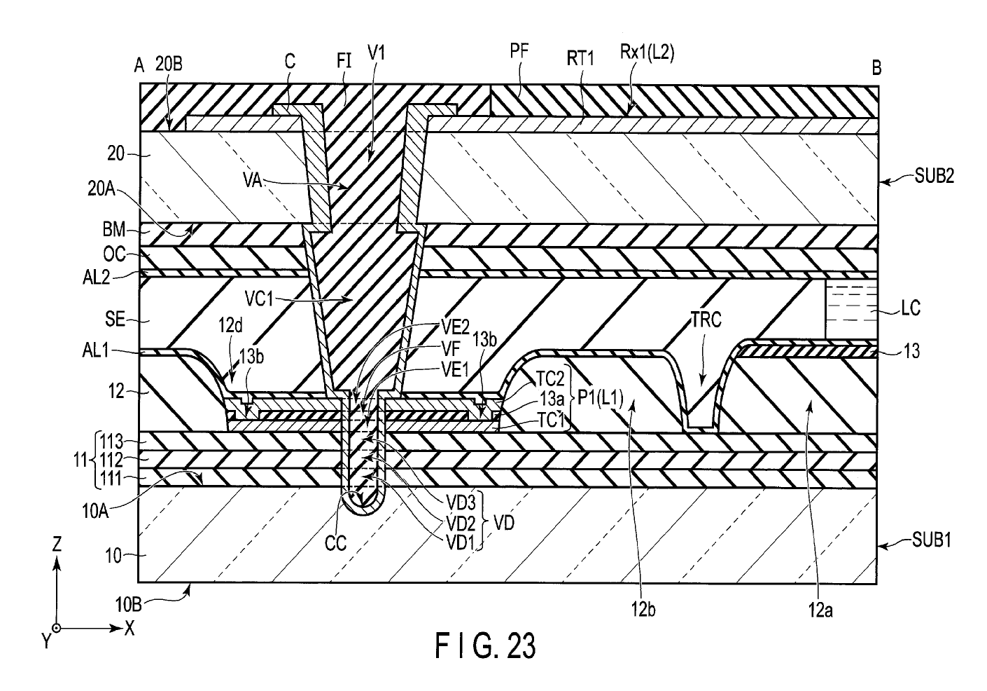

FIG. 23 shows the twelfth modification of the display device DSP according to the present embodiment. The twelfth modification differs from the eleventh modification in that the inorganic insulating layer 13a is provided between the transparent conductive layer TC1 and the transparent conductive layer TC2.

The inorganic insulating layer 13a is formed of silicon nitride, for example. For example, the inorganic insulating layer 13a and the transparent conductive layer TC1 shown in FIG. 15 have the same shape. As long as the inorganic insulating layer 13a is provided at least around the contact hole V1, the inorganic insulating layer 13a can be formed in any shape and is not necessarily formed in the shape shown in the drawing. The inorganic insulating layer 13a can be formed simultaneously with the third insulating layer 13, for example.

The inorganic insulating layer 13a has the groove 13b which exposes part of the transparent conductive layer TC1. The transparent conductive layer TC1 and the transparent conductive layer TC2 contact each other in the groove 13b. Accordingly, the transparent conductive layer TC1 and the transparent conductive layer TC2 are electrically connected to each other. For example, the groove 13b has the same shape as that of the example shown in FIG. 18.

The contact hole V1 does not include the hole VC2 but includes the hole VF. The hole VF is continuous with the hole VE1 and the hole VE2. In the example illustrated, the connecting material C contacts the transparent conductive layer TC2 in the holes VC1 and VE2, contacts the inorganic insulating layer 13a in the hole VF, and contacts the transparent conductive layer TC1 in the hole VE1.

The same effect produced from the tenth modification can be produced from the present modification. Further, since the inorganic insulating layer 13a formed of silicon nitride is provided on the transparent conductive layer TC1, the same effect produced from the eighth modification can be produced from the present modification.

### Thirteenth Modification

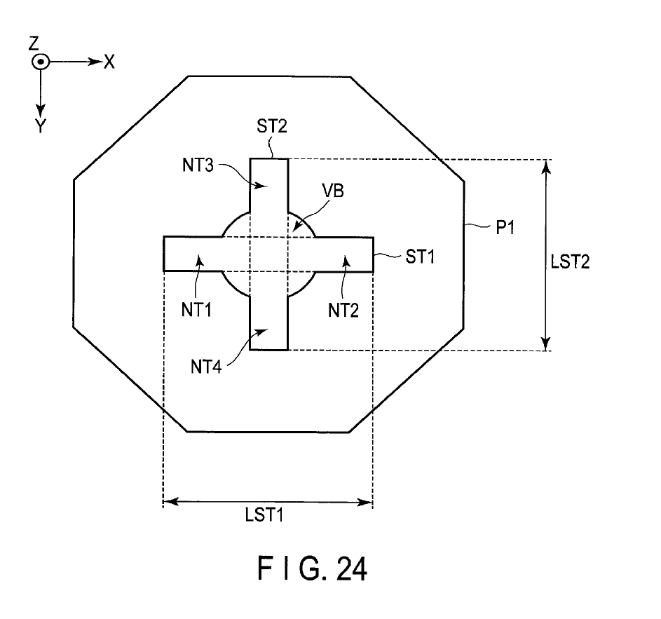

FIG. 24 is a plan view showing the thirteenth modification of the display device DSP according to the present embodiment. The thirteenth modification differs from the example shown in FIG. 7 in that the slits provided in the pad P1 intersect the hole VB. Here, wiring lines are omitted.

In the example illustrated, the pad P1 has two intersecting slits ST1 and ST2. For example, the slit ST1 extends in the first direction X and has a length LST1 in the first direction X. The slit ST2 extends in the second direction Y and has a length LST2 in the second direction Y. The length LST1 and the length LST2 are equal to each other in the example illustrated but may be different from each other.

The hole VB is provided in the vicinity of the intersection of the slit ST1 and the slit ST2. In the example illustrated, the diameter of the hole VB is less than the lengths LST1 and LST2, and the hole VB entirely overlaps the slits ST1 and ST2. In other words, the pad P1 has four notches NT1 to NT4 which are continuous with the hole VB and extend outward beyond the hole VB. For example, the notch NT1 and the notch NT2 are located on the same line in the first direction X. The notch NT3 and the notch NT4 are located on the same line in the second direction Y.

As long as the slit ST1 and the slit ST2 intersect each other, extension directions thereof are not limited to any particular directions. For example, the slit ST1 may extend in a direction intersecting the first direction X, and the slit ST2 may extend in a direction intersecting the second direction Y. Further, three or more slits may intersect each other.

According to the present modification, the amount of the conductive material which forms the pad P1 will be reduced in the vicinity of the intersection of the slit ST1 and the slit ST2. Therefore, when the hole VB is formed by applying a laser beam to the vicinity of the intersection of the slit ST1 and the slit ST2, for example, generation of a molten material from the pad P1 will be prevented. Therefore, the reliability of contact between the pad P1 and the connecting material C can be increased.

### Fourteenth Modification

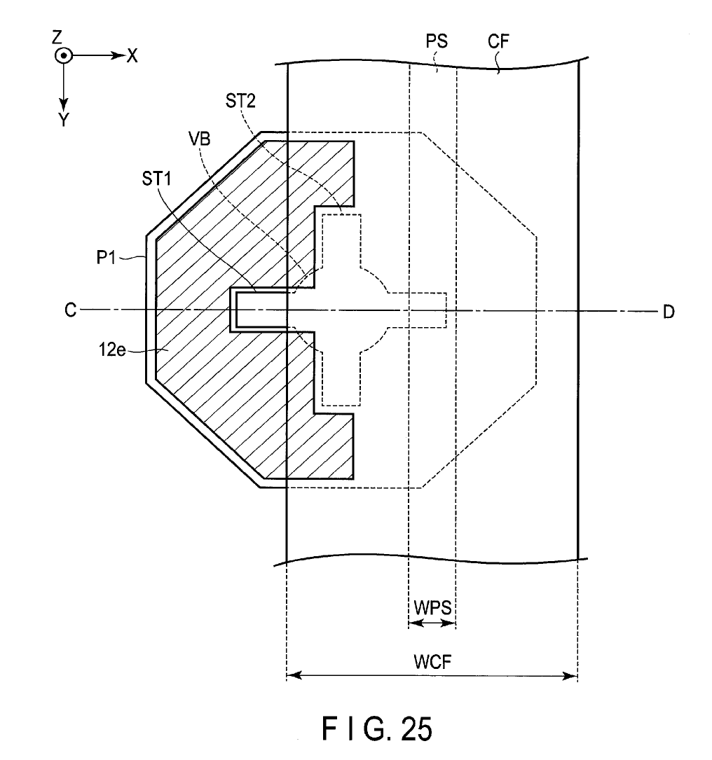

FIG. 25 shows the fourteenth modification of the display device DSP according to the present embodiment. The fourteenth modification differs from the example shown in FIG. 1 in that a spacer PS and the color filer CF are provided in an area which overlaps the pad P1. Here, the pad P1 has the same shape as that of the example shown in FIG. 24.

For example, the spacer PS and the color filter CF extend in the second direction Y and are formed into strips having substantially constant widths, respectively. A width WCF of the color filter CF is greater than a width WPS of the spacer PS. Here, the widths WCF and WPS correspond to a dimension in the first direction X. The spacer PS entirely overlaps the color filter CF. In the example illustrated, the spacer PS is located substantially at the center of the color filter CF in the first direction X.

In the example illustrated, the color filter CF overlaps the entire slit ST2 and the entire hole VB and overlaps part of the slit ST1. On the other hand, the spacer PS does not overlap the hole VP and the slit ST2 but overlaps one end of the slit ST1 in the first direction X.

The second insulating layer 12 has a groove 12e in an area which overlaps substantially half of the pad P1 as shown by diagonal lines in the drawing. The groove 12e partially overlaps the color filter CF but does not overlap the spacer PS. In other words, the second insulating layer 12 is provided in an area which at least overlaps the spacer PS. In the example illustrated, the groove 12e hardly overlaps the slits ST1 and ST2 and the hole VB.

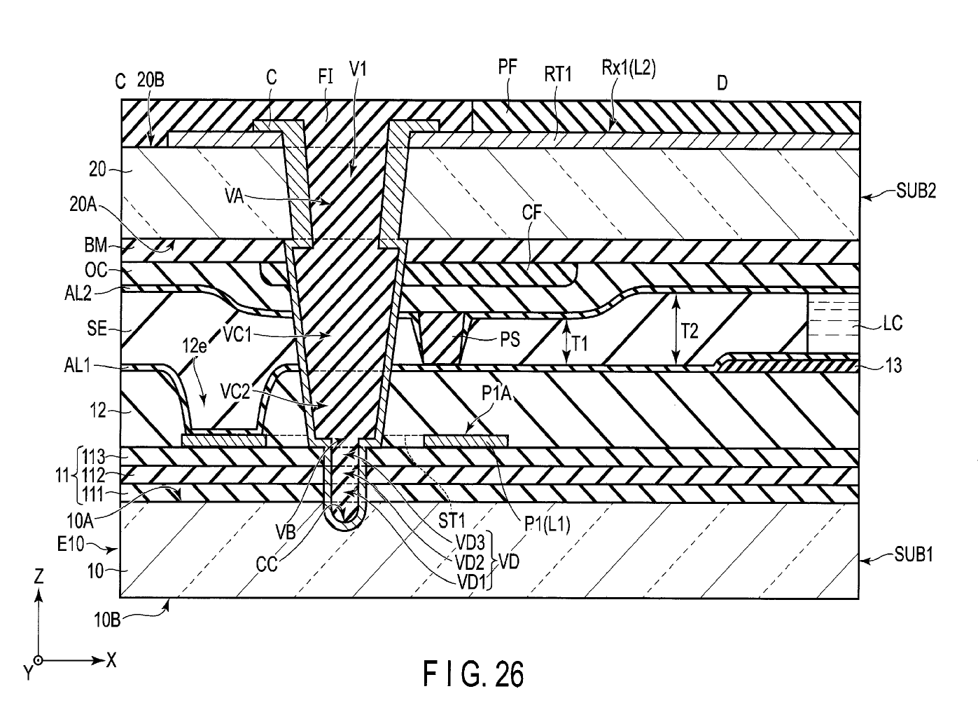

FIG. 26 is a sectional view taken along line C-D of FIG. 25. The color filter CF is located between the light-shielding layer BM and the overcoat layer OC on the second substrate SUB2. The spacer PS is located between the overcoat layer OC and the first alignment film AL1. In the example illustrated, the second alignment film AL2 covers the overcoat layer OC and also covers the side surfaces of the spacer PS. The spacer PS may not be covered with the second alignment film AL2.

A thickness T1 of the sealant SE in an area in which the color filter CF is provided is less than a thickness T2 of the sealant SE in an area in which the color filter CF is not provided. Here, the thicknesses T1 and T2 are defined in an area in which the second insulating layer 12 is provided and correspond to a gap between the first alignment film AL1 and the second alignment film AL2 in the third direction Z. The spacer PS contacts the first alignment film AL1 in the example illustrated but may not contact the first alignment film AL1. When the spacer PS is provided, the sealant SE will be prevented from entering the liquid crystal layer LC side.

In the example illustrated, the hole VC1 penetrates the color filter CF in addition to the light-shielding layer BM, the overcoat layer OC, the first alignment film AL1, the second alignment film AL2 and the sealant SE. That is, the connecting material C contacts the color filter CF in the hole VC1.

The pad P1 is located on the inorganic insulating layer 113. The pad P1 is covered with the second insulating layer 12 but is partially exposed by the groove 12e. In the groove 12e, the first alignment film AL1 contacts the pad P1. Since the hole VB is continuous with the slit ST1 in a plan view as described above, the hole VB is not shown in this sectional view. In the example illustrated, the connecting material C contacts the inorganic insulating layer 113 in the hole VC2. The same effect produced from the thirteenth modification can be produced from the present modification.

### Fifteenth Modification

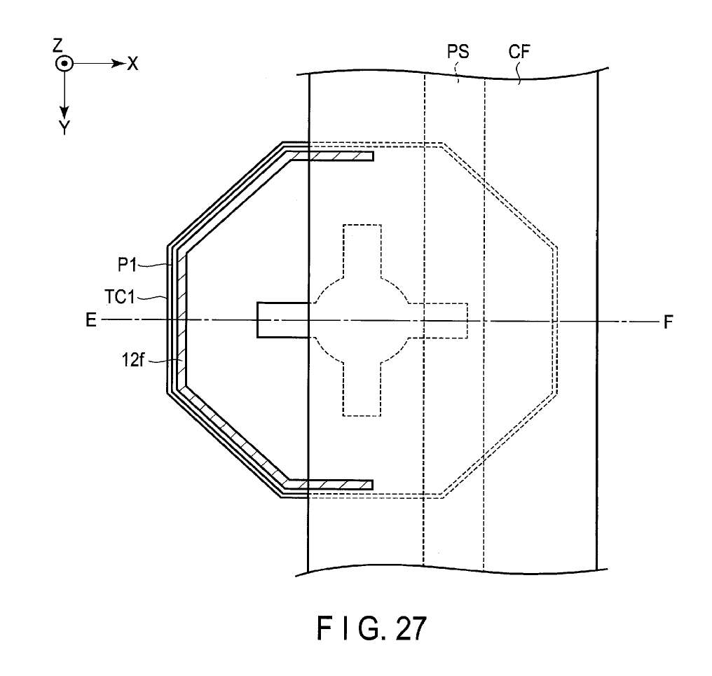

FIG. 27 shows the fifteenth modification of the display device DSP according to the present embodiment. The fifteenth modification differs from the fourteenth modification in that the transparent conductive layer TC1 which overlaps the pad P1 is provided.

For example, the transparent conductive layer TC1 and the pad P1 have about the same size and shape. The second insulating layer 12 has a groove 12f as shown by diagonal lines in the drawing. The groove 12f entirely overlaps the pad P1 and the transparent conductive layer TC1. The groove 12f is provide along the outer edges of the pad P1 in an area corresponding to substantially half of the pad P1. In the example illustrated, both ends of the groove 12f, that is, the portions which extend in the first direction X overlap the color filter CF.

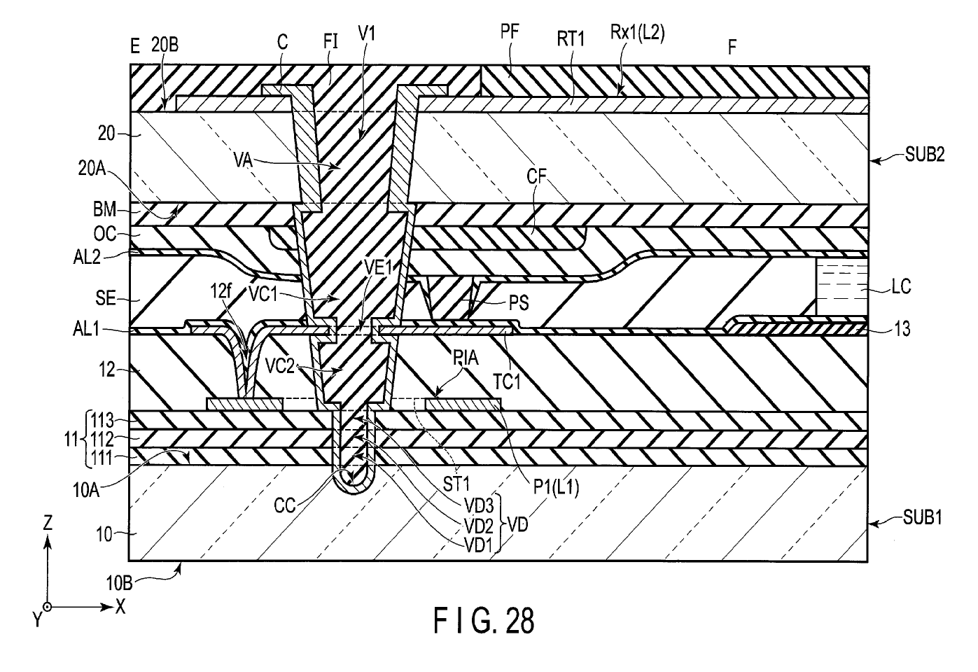

FIG. 28 shows a sectional view taken along line E-F shown in FIG. 27. The transparent conductive layer TC1 is located above the second insulating layer 12 and contacts the pad P1 in the groove 12f. The contact hole V1 has the hole VE1 which penetrates the transparent conductive layer TC1, in addition to the holes VA, VC1, VC2 and VD and the concavity CC. The connecting material C contacts the transparent conductive layer TC1 in the holes VC1 and VC2. In the example illustrated, the connecting material C also contacts the transparent conductive layer TC in the hole VE1.

The same effect produced from the thirteenth modification can be produced from the present modification. Further, since the transparent conductive layer TC1 contacts the pad P1 in the groove 12f and is electrically connected to the pad P1, when the transparent conductive layer TC1 contacts the connecting material C in the contact hole V1, the contact area of the pad P1 and the connecting material C can be substantively increased.

In the above-described embodiment, the wiring line W1 which is arranged in the non-display area NDA and is electrically connected to the pad P1 may be formed on the inorganic insulating layer 113 even when the pad P1 is formed on any of the first basement 10, the inorganic insulating layer 111, the inorganic insulating layer 112, the inorganic insulating layer 113 and the semiconductor layer SC. Alternatively, the wiring line W1 and the pad P1 may be formed on the same insulating material. That is, the wiring line W1 may be formed on the first basement 10 if the pad P1 is formed on the first basement 10, the wiring line W1 may be formed on the inorganic insulating layer 111 if the pad P1 is formed on the inorganic insulating layer 111, and the wiring line W1 may be formed on the inorganic insulating layer 112 if the pad P1 is formed on the inorganic insulating layer 112. Further, the wiring line W1 may be formed of the same material as that of the signal line S, may be formed of the same material as that of the scanning line G, or may be formed of the same material as that of the metal layer M shown in FIG. 3, for example.

In the present embodiment, the pad P1 corresponds to the first conductive layer L1, and the detection electrode Rx1 corresponds to the second conductive layer L2. The second insulating layer 12 corresponds to the organic insulating layer, the first insulating layer 11 corresponds to the first inorganic insulating layer, and the inorganic insulating layer 13a corresponds to the second inorganic insulating layer. The hole VA corresponds to the first hole, the hole VC1 corresponds to the second hole, and the hole VC2 corresponds to the third hole. Further, the groove 13b corresponds to the first groove, the grooves 12c and 12f correspond to the second groove, and the groove 12e corresponds to the third groove.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a first basement;
a second basement which is opposed to the first basement and has a first hole;
a first conducive layer which is located between the first basement and the second basement and is opposed to the first hole;
a sealant which is located between the first conductive layer and the second basement and has a second hole which is continuous with the first hole;
an organic insulating layer which is located between the first conductive layer and the sealant and has a third hole which is continuous with the second hole;
a second conductive layer which is located on a surface of the second basement opposite to a surface of the second basement which is opposed to the first basement; and
a connecting material which electrically connects the first conductive layer and the second conductive layer via the first hole to third hole.

2. The display device of claim 1, wherein the first conductive layer contacts a surface of the first basement which is opposed to the second basement.

3. The display device of claim 1, further comprising a first inorganic insulating layer which is located between the first conductive layer and the first basement, wherein
the first conductive layer contacts the first inorganic insulating layer.

4. The display device of claim 1, further comprising a semiconductor layer which is located between the first conductive layer and the first basement, wherein
the first conductive layer contacts the semiconductor layer.

5. The display device of claim 1, further comprising a transparent conductive layer which is located between the organic insulating layer and the sealant, wherein
the transparent conductive layer contacts the first conductive layer in a groove which is provided in the organic insulating layer, and
the connecting material contacts the transparent conductive layer.

6. The display device of claim 5, wherein the groove is provided in the shape of a ring which surrounds the third hole in a plan view.

7. The display device of claim 1, further comprising:
a first transparent conductive layer and a second conductive layer which are located between the organic insulating layer and the sealant; and
a second inorganic insulating layer which is located between the first transparent conductive layer and the second transparent conductive layer, wherein
the first transparent conductive layer contacts the second transparent conductive layer in a first groove which is provided in the second inorganic insulating layer,
at least one of the first transparent conductive layer and the second transparent conductive layer contacts the first conductive layer in a second groove which is provided in the organic insulating layer, and
the connecting material contacts the first transparent conductive layer and the second transparent conductive layer.

8. The display device of claim 7, wherein
the second groove is provided in the shape of a ring which surrounds the third hole in a plan view, and
the first groove is provided in the shape of a ring which surrounds the second groove in a plan view.

9. The display device of claim 1, further comprising a spacer which is located between the organic insulating layer and the second basement and overlaps the first conductive layer in a plan view.

10. The display device of claim 9, further comprising a color filter which is located between the spacer and the second basement and overlaps the first conductive layer and the spacer in a plan view, wherein
the connecting material contacts the color filter.

11. The display device of claim 10, wherein the organic insulating layer has a third groove which overlaps the color filter and the first conductive layer in a plan view.

12. A display device comprising:
a first basement;
a second basement which is opposed to the first basement and has a first hole;
a first conductive layer which is located between the first basement and the second basement and is opposed to the first hole;
a sealant which is located between the first conductive layer and the second basement and has a second hole which is continuous with the first hole;
a second conductive layer which is located on a surface of the second basement opposite to a surface of the second basement which is opposed to the first basement; and
a connecting material which electrically connects the first conductive layer and the second conductive layer via the first hole and the second hole, wherein
the first conductive layer is a transparent conductive layer.

13. The display device of claim 12, further comprising an organic insulating layer which is located between the first conductive layer and the first basement, wherein
the first conductive layer contacts the organic insulating layer.

14. The display device of claim 12, further comprising a first inorganic insulating layer which is located between the first conductive layer and the first basement, wherein
the first conductive layer contacts the first inorganic insulating layer.

15. The display device of claim 12, further comprising a metal layer which is located between the first conductive layer and the first basement, wherein
the first conductive layer contacts the metal layer.

16. The display device of claim 12, wherein
the first conductive layer comprises a first transparent conductive layer and a second transparent conductive layer,
the display device further comprising:
a second inorganic insulating layer which is located between the first transparent conductive layer and the second transparent conductive layer, wherein
the first transparent conductive layer contacts the second transparent conductive layer in a groove which is provided in the second inorganic insulating layer.
